(19) United States
(12) Patent Application Publication
(10) Pub. No.: US 2016/0071655 A1
(43) Pub. Date: Mar. 10, 2016

(54) ELECTROCHEMICAL SOLAR CELLS

(71) Applicants: THE REGENTS OF THE UNIVERSITY OF CALIFORNIA, Oakland, CA (US); COSMO CHEMICAL CO., LTD, Incheon (KR); COSMO AM&T CO., LTD., Chungbuk (KR)

(72) Inventors: Yuelong Li, San Diego, CA (US); Michael B. Frank, San Diego, CA (US); Michael J. Tauber, San Diego, CA (US); Sungho Jin, San Diego, CA (US); Jung Keun Ryoo, Incheon (KR); Hyuck Jung, Daejeon (KR)

(21) Appl. No.: 14/782,585

(22) PCT Filed: Apr. 4, 2014
(86) PCT No.: PCT/US14/33093

§ 371 Date: Oct. 5, 2015

Related U.S. Application Data
(60) Provisional application No. 61/808,575, filed on Apr. 4, 2013.

(51) Int. Cl. H01G 9/20; H01L 31/18

(52) U.S. Cl. CPC H01G 9/2031; H01G 9/2022; H01G 9/2059; H01G 9/2004; H01G 9/2009; H01L 31/1888; Y10S 977/734; Y10S 977/811; Y10S 977/948; B82Y 30/00

(57) ABSTRACT

Methods, systems, and devices are disclosed for implementing and fabricating electrochemical solar cells including dye-sensitized and perovskite-sensitized solar cells. In one aspect, a dye-sensitized solar cell device includes a cathode including a metal mesh structure that is optically transmissive and electrically conductive, an anode including a metal base layer that is optically opaque and electrically conductive, one or more layers of a semiconductive oxide coupled to the anode, the one or more layers of the semiconductive oxide including nanostructures having a photosensitive dye material coating, in which the anode generates photoelectric energy based on absorption of light by the photosensitive dye material, and an electrolyte of a substantially transparent substance and formed between the cathode and the one or more layers of a semiconductive oxide.

### CROSS-REFERENCE TO RELATED APPLICATIONS

This patent document claims benefit of priority of U.S. Provisional Patent Application No. 61/808,575, entitled “DYE-SENSITIZED SOLAR CELLS,” and filed on Apr. 4, 2013. The entire content of the aforementioned patent application is incorporated by reference as part of the disclosure of this patent document.

### TECHNICAL FIELD

This patent document relates to solar cell technologies.

### BACKGROUND

A photovoltaic or solar cell is an electrical device that converts the energy of light directly into electricity by the photovoltaic effect. For example, when a photovoltaic cell is exposed to light, the cell can generate and support an electric current, e.g., without electrical connection to an external voltage source.

### SUMMARY

Techniques, devices, and systems are described for implementing electrochemical solar cells, e.g., including dye-sensitized solar cells (DSSCs) and/or perovskite-sensitized solar cells (PSSCs) with metal electrodes for both the anode and cathode.

In one aspect, a dye-sensitized solar cell device includes a cathode including a metal mesh structure that is optically transmissive and electrically conductive, an anode including a metal base layer that is optically opaque and electrically conductive, one or more layers of a semiconductive oxide coupled to the anode, the one or more layers of the semiconductive oxide including nanostructures having a photosensitive dye material coating, in which the anode generates photoelectric energy based on absorption of light by the photosensitive dye material, and an electrolyte of a substantially transparent substance and formed between the cathode and the one or more layers of a semiconductive oxide. For example, the dye-sensitized solar cell device can operate by back-illumination, whereby the light (e.g., sunlight) first passes through the highly transmissive mesh cathode, then through a thin layer of the transparent electrolyte, and is next absorbed by the photoactive anode structure. The semiconductive oxide layer(s) of the anode structure can include a titanium oxide film (e.g., including titanium dioxide (TiO₂) film) and a photosensitive dye coated on the TiO₂ films.

In another aspect, a dye-sensitized solar cell device includes a cathode; an anode; a photoactive layer coupled to the anode comprising one or more layers of a semiconductive oxide including nanostructures, in which at least some of the nanostructures are coated by a photosensitive dye material; and an electrolyte of a substantially transparent substance between the cathode and photoactive layer, in which the device generates photoelectric energy based on absorption of light transmitted to the photoactive layer through an optically transmissive metal electrode structure functioning as the cathode or the anode, or both.

In another aspect, a perovskite-sensitized solar cell device includes a cathode; an anode; a perovskite sensitizer layer configured between the anode and the cathode comprising one or more layers of a perovskite crystals; an electrolyte coupled between the cathode and perovskite sensitizer layer and formed of a substantially transparent substance capable of conducting hole charge carriers; and one or more layers of a semiconductive oxide nanostructures coupled between the cathode and perovskite sensitizer layer capable of transferring electrons to the anode, in which the device generates photoelectric energy based on absorption of light transmitted to the perovskite sensitizer layer through an optically transmissive metal electrode structure functioning as the cathode or the anode, or both.

In another aspect, a solar cell device comprising a cathode, an anode, a semiconductive oxide layer(s), and an electrolyte, in which the solar cell device is fabricated by a method comprising: producing a metal base layer by cutting a metallic foil and cleaning the metallic foil; producing a metal mesh structure by a direct patterning process or a toner transfer process; forming one or more layers of a semiconductive oxide formed on the metal base layer, in which the semiconductive oxide includes nanostructures having a photosensitive dye material coating; and assembling the electrolyte between the metal mesh structure and the semiconductive oxide layer(s) coupled to the metal base layer, in which an optically transmissive cathode of the solar cell includes the metal mesh structure, an optically opaque anode of the solar cell includes the metal base layer having the one or more layers of a semiconductive oxide formed on the metal base layer, such that the anode generates photoelectric energy based on absorption of light by the photosensitive dye material. The direct pattering process includes producing a design pattern of a mesh, printing the design pattern on a metal foil to form a pattern-masked metal foil, cleaning the pattern-masked metal foil, and chemically etching the pattern-masked metal foil. The toner transfer process includes producing a design pattern of a mesh, printing the design pattern on a transfer material including a printable plastic or a paper, applying heat and pressure to the transfer material on a metal sheet to form a pattern-masked metal sheet, cleaning the pattern-masked metal sheet, and chemically etching the pattern-masked metal sheet.

In another aspect, a method for constructing a dye-sensitized solar cell includes coating TiO₂ film layer by layer, drying process in between each layer coating, and annealed anatase structure on a surface of a metallic substrate. Implementations of the method can optionally include one or more of the following exemplary features. The method can include coating layered TiO₂ film on the surface of metal substrate, and having an anode structure with layered TiO₂ film with certain thickness, order and number of layers. The method can include using a metal wire or a foil substrate as a conduit for photo-generated electrons from surfaces of the TiO₂ anode without a conductive transparent glass. The surfaces of TiO₂ nanoparticle can be dye coated.

The subject matter described in this patent document can be implemented in specific ways that provide one or more of the following features. For example, the described techniques, apparatus and systems can potentially provide one or more of the following advantages. The DSSC and PSSC devices described herein can include new architectures that do not require any transparent conductive oxide (TCO) on glass or fluorinated tin oxide (FTO)-glass at either the anode or cathode electrode, which can result in an increase in efficiency, simplified design, and ease of scaling. Metal has resistive losses that are orders of magnitude smaller than TCO. Moreover, because the TCO is one of the most costly components of a sensitized solar cell, the avoidance of this material by utilizing all metallic electrodes of anode or cathode or both can significantly reduce the overall costs of a DSSC or PSSC, which can allow easier commercialization and more widespread deployment of the DSSC or PSSC solar cells around the world.

### BRIEF DESCRIPTION OF THE DRAWINGS

FIGS. 1A-1C show schematic illustrations of exemplary embodiments of dye-sensitized solar cell devices of the disclosed technology.

FIG. 2A shows an illustrative schematic of an exemplary back-illuminated dye-sensitized solar cell device including a transmissive metal mesh cathode and a substantially opaque solid anode, depicting three exemplary configurations of photoactive layer(s) coupled to the anode.

FIG. 2B shows a scanning electron microscopy (SEM) image showing TiO₂ nanotubes on an exemplary anode Ti foil made by anodization.

FIG. 3 shows an exemplary electron micrograph depicting ˜8 nm diameter TiO₂ nanotubes synthesized by an exemplary hydrothermal process.

FIGS. 4A and 4B show comparative SEM images of exemplary TiO₂ anode structure layers without and with nanofibers.

FIGS. 5A and 5B show cross-sectional schematic illustrations of dye-sensitized solar cells including all-metal substrates and a photoactive region including a gradient of exemplary TiO₂ nanoparticle sizes for enhanced solar cell performance.

FIG. 6 shows a schematic illustration of an exemplary layered anode structure for DSSCs fabricated in combination with a metal mesh substrate.

FIG. 7 shows an SEM image of an exemplary layered anode structure, where the amount of large scattering TiO₂ nanoparticles is varied in each layer.

FIG. 8 shows a data plot of photocurrent voltage (I-V) curves of exemplary back-illuminated DSSCs fabricated with layered structured TiO₂ anode on a metal substrate.

FIG. 9 shows a photocurrent voltage (I-V) plot of an exemplary large-size back-illuminated DSSC device.

FIG. 10 shows a comparative schematic diagram of exemplary back-illuminated DSSC devices having a less transparent electrolyte versus a transparent/colorless electrolyte.

FIG. 11 shows a schematic illustration of a back-illuminated DSSC showing the top (cathode) side.

FIGS. 12A-12C show diagrams depicting exemplary designs of a cathode metal wire arrangement.

FIGS. 13A and 13B show SEM images of an exemplary Ti mesh cathode structure.

FIGS. 14A-14F show schematic illustrations of exemplary embodiments of FTO-glass-free perovskite-sensitized solar cell devices of the disclosed technology.

FIG. 15A shows an illustrative schematic of an exemplary back-illuminated FTO-glass-free perovskite-sensitized solar cell device including a transmissive metal mesh cathode and a substantially opaque solid anode, depicting three exemplary configurations of semiconductive oxide nanostructure layer(s) coupled to the anode.

FIG. 15B shows an SEM image showing TiO₂ nanotubes on an exemplary anode Ti foil made by anodization.

FIG. 16 shows a flow diagram of an exemplary low-cost, high throughput printer-based fabrication method to produce metal mesh electrodes for exemplary electrochemical solar cells of the disclosed technology.

FIG. 17A shows an SEM image of an exemplary hexagonal pattern produced by the exemplary inexpensive printing method.

FIG. 17B shows images of exemplary slotted metal mesh conductor screens fabricated by the disclosed printer-based pattern masking and chemical etching techniques.

FIGS. 18A and 18B show schematic illustrations of exemplary sunlight harvesting device configurations.

### DETAILED DESCRIPTION

Commercial photovoltaics are based upon solid state materials, with silicon (Si) the prevalent semiconductor in commercial cells. The bandgap of silicon (1.1 eV) is well-matched to the solar spectrum at the Earth's surface. Cells with efficiencies as high as 20% can be obtained commercially, and even higher efficiencies are measured in the laboratory setting. However, the low absorbance of crystalline Si (c-Si) requires that the active material be hundreds of microns thick for effective absorption of solar photons. A large portion of the cost of c-Si cells can be attributed directly to the need for large amounts of the high-purity Si. A number of alternatives to these cells utilize layers with far greater absorption than c-Si, and therefore these cells can efficiently capture sunlight with thicknesses closer to 10 microns. Most notable among these thin-film cells are amorphous silicon (a-Si) and the semiconductors cadmium telluride (CdTe), copper indium selenide (CIS) or copper indium selenide (CIGS). These materials have emerged commercially, but are still in need of further development because of stability, scarcity of the indium and tellurium, or concerns about environmental impact.

Another type of solar cell technology is based upon photoelectrochemistry and upon the absorption and excited-state properties of dye molecules that are bound to a titanium dioxide (TiO₂) substrate. Cells of this type, initially reported by O'Regan and Gratzel in 1991, are now termed “Gratzel cells” or dye-sensitized solar cells (DSSCs). These cells use environmentally-friendly materials, enable ease of manufacture, and potentially at much lower cost than Si-based solar cells. Currently, the deployment of these cells have been hampered by the high resistivity and cost of transparent substrates that are integral to their design.

Conventional DSSCs are fabricated with transparent conducting oxide coated on glass (TCO/glass). However, due to the high resistance (e.g., typically 8-15 ohms/square) and cost of TCO/glass, for example, there are difficulties with scaling this design of solar cells to large areas while maintaining the cost advantage of DSSCs. Metal substrates have important advantages relative to TCO/glass for DSSCs. For example, the high conductivity of metal substrates is an essential characteristic for the construction of large-area (e.g., ˜100 cm²) single module DSSCs. However, the opacity of metal electrodes requires architectures that are different from those of traditional DSSCs based on TCO/glass. Therefore the strategies of the disclosed technology utilize metal-substrate designed in unique configurations to produce various types of solar cells, e.g., without TCO/glass or fluorinated tin oxide (FTO)-glass.

Devices, systems, and methods are described for fabricating and implementing electrochemical solar cells for back-illumination, front-illumination, and both back- and front-illumination using various configurations of metallic substrates for the anode and cathode electrodes. The disclosed electrochemical solar cells include dye-sensitized solar cells (DSSCs) and perovskite-sensitized solar cells (PSSCs).

In one aspect, the disclosed technology includes high efficiency dye-sensitized solar cell devices. The DSSC devices include a cathode, an anode coupled to one or more layers of a semiconductive oxide including nanostructures having a photosensitive dye material coating, and an electrolyte of a substantially transparent substance between the cathode and anode, in which the DSSC device generates photoelectric energy based on absorption of light transmitted to the photosensitive dye material through an optically transmissive electrode acting as the cathode, or the anode, or both. Either the cathode or the anode, or both the cathode and the anode, can be configured as a metal mesh structure or metal line array structure permitting transmittance of light through the electrode structure to other portions of the DSSC device. When light is received and transmitted through the DSSC device to the photosensitive photoactive region, the absorption of photons by the photosensitive dye coating results in electron transfer from the excited-state photosensitive dye directly to the conduction band of the nanostructures of the semiconductive oxide and are captured by the anode. Concurrently, the electrolyte provides electrons that can replenish the photosensitive dye material, and the cathode can provides electrons to the electrolyte after flow from a connected circuit between the anode and the cathode.

In one exemplary embodiment, an exemplary back-illuminated DSSC device includes an opaque metal-based anode, in which an anode structure includes a TiO₂ film and a photosensitive dye coated on the TiO₂ films on the opaque metal-based anode, a semi-transparent metal mesh cathode having high optical transmittance, and a transparent electrolyte. The anode can provide back-illumination of the light transmitted through the optically transmissive (semi-transparent) cathode and the transparent electrolyte. In some implementations, the anode can include a metal foil overlaid with a gradient film of TiO₂ nanoparticles. For example, the anode structure can be formed by coating the foil with multiple layers of TiO₂ nanoparticle pastes, e.g., each having a different amount of scattering nanoparticles. The cathode can include a platinized Ti metal mesh with 90% light transmission. The DSSC device can be operated whereby light (e.g., such as sunlight) first passes through a highly transmissive mesh cathode, then through a thin layer of transparent electrolyte, and is next absorbed by the photoactive anode.

For example, light (e.g., such as sunlight) can penetrate the dye-sensitized solar cell device through the optically transmissive cathode and the transparent electrolyte to the anode, and photons are absorbed by the photosensitive dye coated to the TiO₂ material, in which the absorption of photons by the photosensitive dye results in electron transfer from the excited-state photosensitive dye directly to the conduction band of the TiO₂ material. Electrons can then diffuse to the metal base of the anode, e.g., as a result of an electron concentration gradient. Concurrently, the electrolyte can provide electrons that can replenish the photosensitive dye material, and the cathode can provides electrons to the electrolyte after flow from a connected circuit between the anode and the cathode.

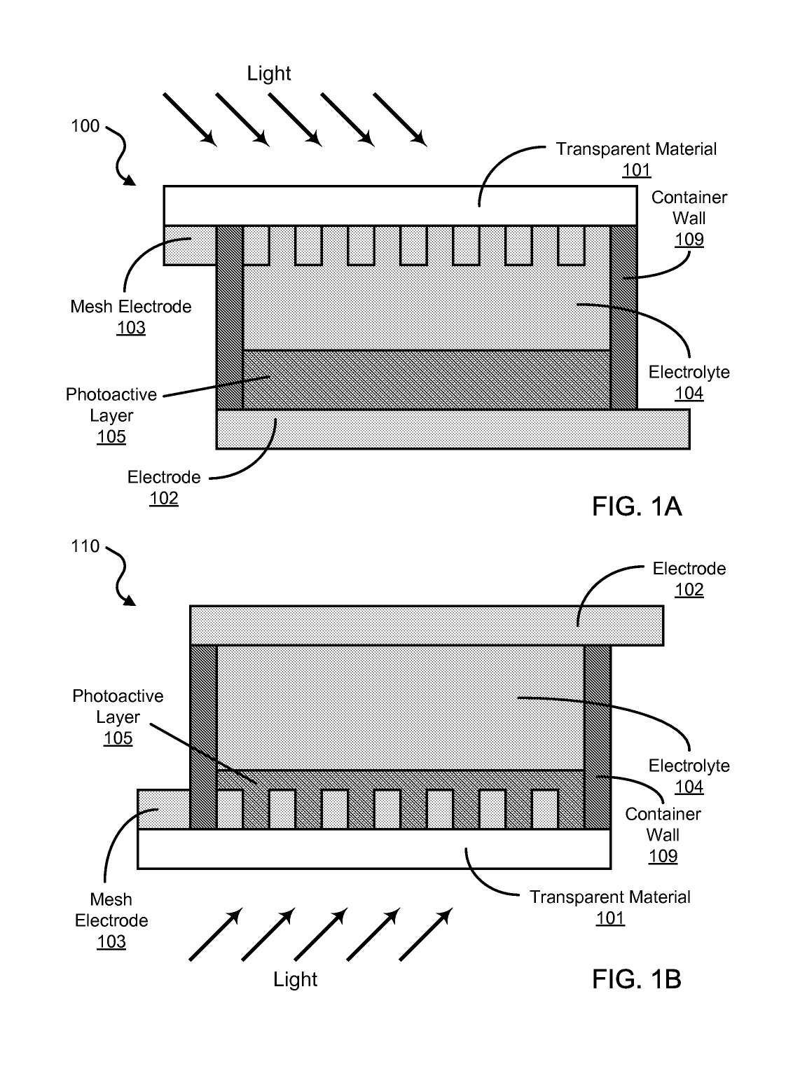

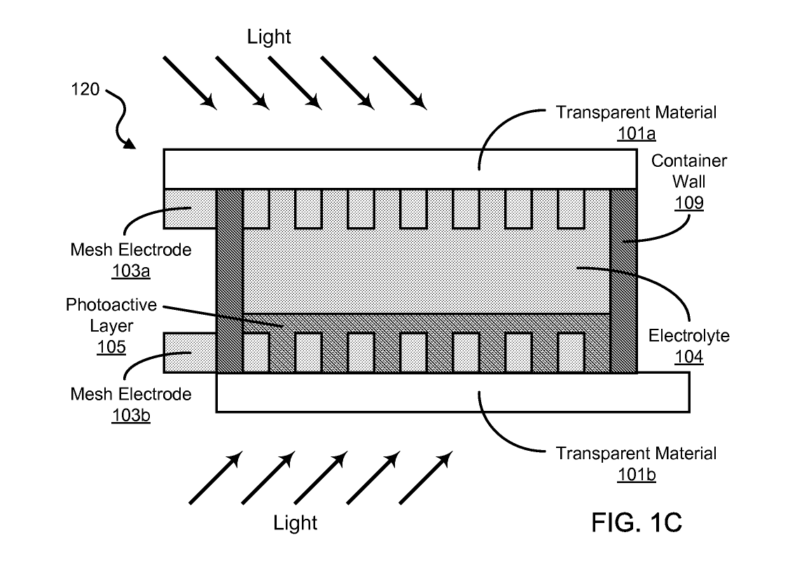

FIGS. 1A-1C show schematic illustrations of three exemplary embodiments of dye-sensitized solar cell devices including all-metallic electrodes to generate photoelectrical energy from light. The all-metallic electrodes of the exemplary solar cell devices of FIGS. 1A-1C can be configured as optically transmissive mesh structure electrodes as well as optically opaque solid structure electrodes that function as the anode or cathode based on their arrangement and coupling with a photoactive region or layer and the electrolyte within the solar cell device structure. For example, the metal mesh screen or structured electrode can be configured as a cathode (e.g., as in the exemplary device 100 of FIG. 1A), as an anode (e.g., as in the exemplary device 110 of FIG. 1B), and as both the cathode and the anode (e.g., as in the exemplary device 120 of FIG. 1C).

FIG. 1A schematically illustrates a solar cell device 100 having a backside illumination DSSC structure that permits intake of light (e.g., sunlight) on an optically transmissive metal mesh electrode 103 functioning as the cathode side of the solar cell 100, in which the anode is configured as a substantially opaque solid electrode 102. The solar cell 100 includes a transparent material 101 configured to face incoming light to receive and transmit light to the mesh electrode 103 coupled to the transparent material 101. For example the transparent material 101 can include a transparent glass or plastic, e.g., including a glass without a TCO coating or FTO-free glass. The mesh electrode 103 can include a metal substrate including a plurality of holes that permit light to pass through the electrode structure into the electrolyte 104 of the solar cell 100. For example, the electrolyte 104 can include a solid, liquid, or gel electrolytic material that is optically transmissive. For example, the mesh electrode 103 can be configured as a metallic mesh structure including a catalyst material, e.g., such as Pt nanoparticles formed on the metallic mesh structure, to function as the cathode of the solar cell 100. The solar cell 100 includes a solid electrode 102 to function as the anode of the solar cell 100. The anode can be configured as a substantially opaque metal substrate, e.g., such as a metal foil including a Ti. The solid electrode 102 is coupled to a photoactive region or layer 105 structured to include one or more layers of a semiconductive oxide including nanostructures, in which at least some of the nanostructures can include a photosensitive dye material coating. For example, the semiconductive oxide can include at least one of titanium dioxide (TiO₂), zinc oxide (ZnO), tin dioxide (SnO₂), zirconium dioxide (ZrO₂), nickel oxide (NiO), niobium pentoxide (Nb₂O₅), tungsten trioxide (WO₃), or iron oxide (Fe₂O₃) nanoparticles, nanorods, or other type nanostructures, or a mixture of two or more of them. The photoactive region 105 is formed between the electrolyte 104 and the anode electrode 102 and contained by a housing or support structure 109 of the solar cell 100. The solar cell 100 can be electrically connected to a circuit between the mesh electrode 103 and the solid electrode 102 in operation for generation of photoelectrical energy from the light.

FIG. 1B schematically illustrates a solar cell device 110 having a frontside illumination DSSC structure that permits intake of light (e.g., sunlight) on the anode side of the solar cell, in which the anode is the optically transmissive metal mesh electrode 103 coupled to the photoactive region or layer 105, and the cathode is configured as the substantially opaque solid electrode 102. The solar cell 110 includes the transparent material 101 coupled to the anode region of the solar cell 110 and configured to face incoming light to receive and transmit light to the anode mesh electrode 103 and photoactive region 105. As in the exemplary embodiments for the solar cell 100, for example, the transparent material 101 of the solar cell 110 can include a transparent glass or plastic, e.g., including a glass without a TCO coating or FTO-free glass. The mesh electrode 103 can be configured in various locations spanning across the photoactive region 105, e.g., including at one end of the photoactive region 105 in contact with the electrolyte 104 or at the other end of the photoactive region 105 in contact with the transparent material 101, or in between. As in the exemplary embodiments for the solar cell 100, for example, the mesh electrode 103 of the solar cell 110 can include a metal substrate including a plurality of holes that permit light to pass through the electrode structure to other regions of the solar cell 120. For example, the electrolyte 104 can include a solid, liquid, or gel electrolytic material that is optically transmissive. For example, the solid electrode 102 can be configured as a substantially opaque metal substrate, e.g., such as a metal foil including a Ti, including a catalyst material, e.g., such as Pt nanoparticles, formed on the metal substrate, to function as the cathode of the solar cell 110. The photoactive region or layer 105 can include one or more layers of a semiconductive oxide including nanostructures, in which at least some of the nanostructures can include a photosensitive dye material coating. For example, the semiconductive oxide can include at least one of TiO₂, ZnO, SnO₂, ZrO₂, NiO, Nb₂O₅, WO₃, or Fe₂O₃ nanoparticles, nanorods, or other type nanostructures, or a mixture of two or more of them. The photoactive region 105 and the electrolyte 104 are contained by the housing or support structure 109 of the solar cell 110. The solar cell 110 can be electrically connected to a circuit between the mesh electrode 103 and the solid electrode 102 in operation for generation of photoelectrical energy from the light.

FIG. 1C schematically illustrates a solar cell device 120 having a dual illumination DSSC structure that permits intake of sunlight or room light coming from either or both electrode sides of the solar cell, in which both the cathode and the anode are optically transmissive metal mesh electrodes. The solar cell 120 includes a transparent material 101a and transparent material 101b coupled to the cathode region and the anode region of the solar cell 120, respectively, and configured to face incoming light to receive and transmit light into the device 120 on both sides. The cathode mesh electrode 103a permits light to transmit through and into the optically transmissive electrolyte 104 to the photoactive region 105. Similarly, the anode mesh electrode 103b permits light to transmit through and into the photoactive region 105. As in the exemplary embodiments for the solar cell 100 or 110, for example, the transparent material 101a and the transparent material 101b of the solar cell 120 can include a transparent glass or plastic, e.g., including a glass without a TCO coating or FTO-free glass. For example, the cathode mesh electrode 103a and the anode mesh electrode 103b of the solar cell 120 can include a metal substrate including a plurality of holes that permit light to pass through the electrode structure to other regions of the solar cell 120. As in the exemplary embodiments for the solar cell 110, for example, the anode mesh electrode 103b of the solar cell 120 can be configured in various locations spanning across the photoactive region 105, e.g., including at one end of the photoactive region 105 in contact with the electrolyte 104 or at the other end of the photoactive region 105 in contact with the transparent material 101b, or in between. For example, the cathode mesh electrode 103a can be configured as a porous metal or metal mesh substrate including a catalyst material, e.g., such as Pt nanoparticles, formed on the metal mesh substrate. For example, the electrolyte 104 can include a solid, liquid, or gel electrolytic material that is optically transmissive. The photoactive region or layer 105 can include one or more layers of a semiconductive oxide including nanostructures, in which at least some of the nanostructures can include a photosensitive dye material coating. For example, the semiconductive oxide can include at least one of TiO₂, ZnO, SnO₂, ZrO₂, NiO, Nb₂O₅, WO₃, or Fe₂O₃ nanoparticles, nanorods, or other type nanostructures, or a mixture of two or more of them. The photoactive region 105 and the electrolyte 104 are contained by the housing or support structure 109 of the solar cell 120. The solar cell 120 can be electrically connected to a circuit between the mesh electrode 103a and the mesh electrode 103b in operation for generation of photoelectrical energy from the light.

For example, the shape and size of the metal mesh electrode 103 can include (i) a plastic-deformation-shaped wire mesh, (ii) a punched-out-from sheet mesh, (iii) a chemical-etch-patterned mesh, (iv) or a multiple-path-wound-wire-mesh, among other configurations. For example, the desired range of mesh segment width and spacing can be controlled in such a way that the light transmitting area is maintained to be at least 50%, or in some examples at least 70%, and in other examples, at least 85% in the DSSC structure. For example, the desired width of the metal mesh segments can be configured in a range including 100 nm to 1,000 micrometer (or in some examples from 1 μm to 500 μm, and in other examples from 2 μm to 200 μm), with the largest dimension of the desired spacing being at least 2 times (or in some examples at least 4 times that of the mesh segment width). In some implementations, for example, the mesh structure of the metal mesh electrode 103 can be configured to have (i) a free-standing mesh geometry, (ii) a wound wire array on the electrode frame, (iii) patterned metal mesh on regular glass substrate by (a) photolithography, (b) micro imprinting, (c) nano-imprinting, or (d) printer-printed thin mesh laid on and attached onto glass substrate, (e) nano-patterned graphene or MoS₂, or metal nano patterns (e.g., with a dimension of 50-2000 nm, or in some examples with 100-1000 nm mesh segment width) to accommodate the relatively short diffusion distance of charge carriers before recombination, e.g., especially for perovskite-sensitized solar cells of the disclosed technology. The nano-patterning of graphene or MoS₂ or metal mesh can be performed by template-assisted method such as anodized aluminum oxide, or by nano-imprinting.

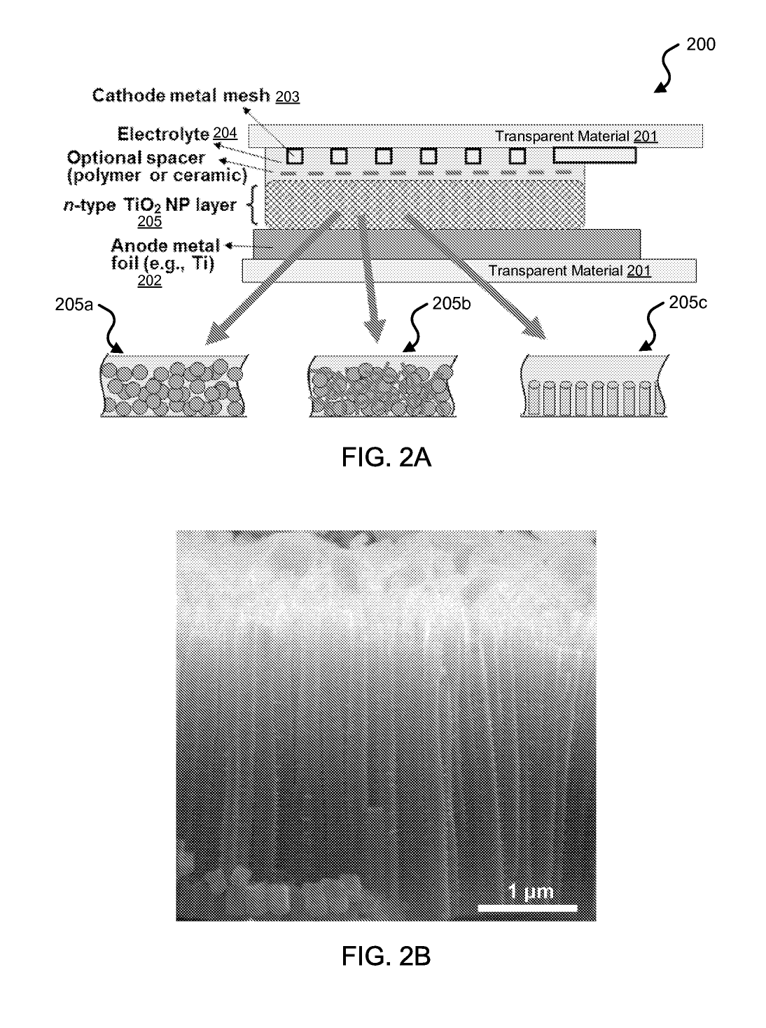

FIG. 2A shows an illustrative schematic of an exemplary back-illuminated dye-sensitized solar cell device 200 including a transmissive metal mesh cathode 203 and a substantially opaque solid anode 202, depicting three exemplary configurations of a photoactive layer(s) 205 including n-type doped titanium oxide (n-TiO₂) layer coupled to the anode electrode 202. The exemplary n-TiO₂ photoactive layers 205 can be configured as a nanostructure 205a structured to include one or more nanoparticle-only layer(s). The exemplary n-TiO₂ photoactive layers 205 can be configured as a nanostructure 205b structured to include one or more nanoparticle layer(s) with embedded nanofibers or nanotubes. For example, the nanostructure 205b can include added carbon nanotubes (CNTs), e.g., which can be double-wall CNT or 8 nm dia TiO₂ nanotubes for enhanced mechanical integrity or charge transfer. The exemplary n-TiO₂ photoactive layers 205 can be configured as a nanostructure 205c structured to include vertical an array of nanotubes. For example, the array of nanotubes can include TiO₂ nanotube array produced by simple anodization of Ti foil substrate for increased surface area and dye adsorption.

For example, the cathode metal mesh electrode 203 can be coated with a very dense coating of Pt nanoparticles. Also, for example, the cathode can be formed of a metal material including at least one of platinum (Pt), gold (Au), silver (Ag), aluminum (Al), or a combination thereof. The exemplary n-TiO₂ photoactive layer 205 in the anode region of the device 200 can have different nano-structural configurations according to the disclosed technology. Three exemplary configurations of the photoactive layer 205 can include the nanoparticle layer configuration 205a, the nanoparticle layer with added nanotubes or nanofibers configuration 205b, and/or the vertical nanotube array configuration 205c, among others. These exemplary nanostructure configurations 205a, 205b, and 205c can be implemented using other semiconductive oxide materials (e.g., including TiO₂, ZnO, SnO₂, ZrO₂, NiO, Nb₂O₅, WO₃, or Fe₂O₃, or mixtures of them) for both DSSC and PSSC devices of the disclosed technology.

FIG. 2B shows an SEM image showing TiO₂ nanotubes on an exemplary anode Ti foil made by anodization, e.g., such as electrochemical anodization etching using 0.5% HF solution (or phosphoric acid or sodium fluoride solution) with e.g., 20-60 V applied, e.g., for 10 min to 5 hr.

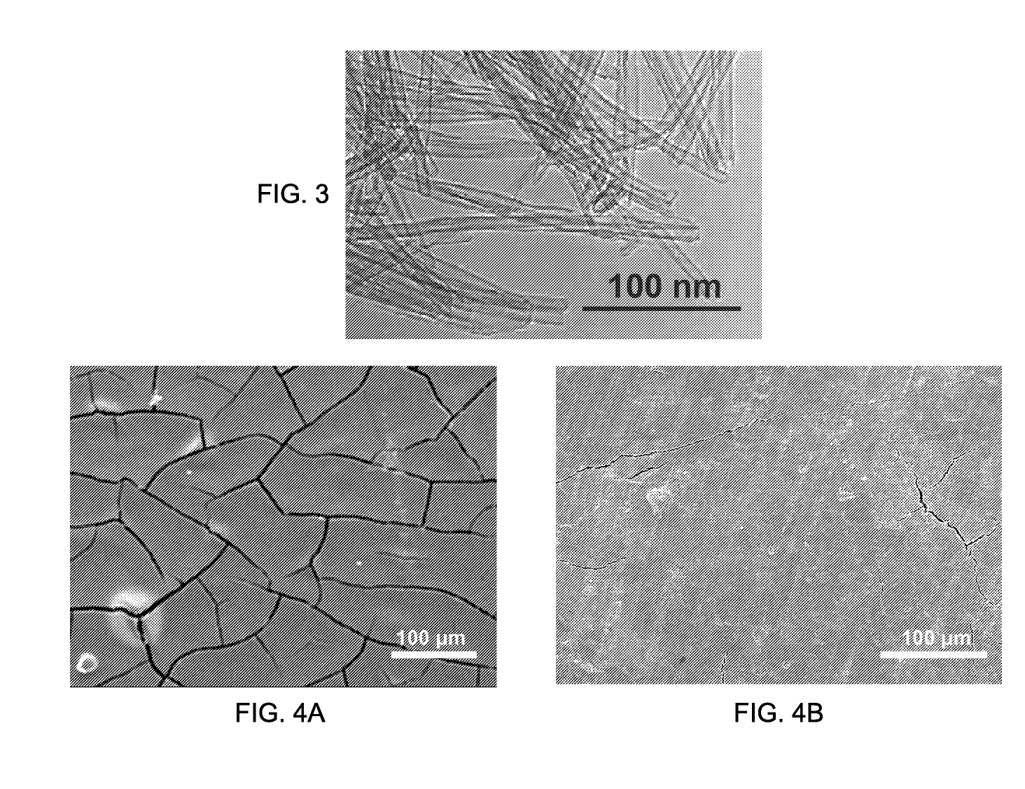

For example, the nanofibers and/or nanotube addition, e.g., such as carbon nanotubes or 8 nm TiO₂ nanotubes, can help mechanical integrity and electrical conduction. In some implementations, for example, a preferred type of carbon nanotubes to be utilized as an elongated filler to the TiO₂ nanoparticle layer is the double-wall carbon nanotubes as they are good conductors (unlike single-wall carbon nanotubes) while maintaining a relatively smaller diameter (as compared to the multi-wall carbon nanotubes). For example, a desired amount of carbon nanotubes to be incorporated in the metal mesh DSSCs can be in an exemplary range of 0.1 to 1 weight %, and in some examples, preferably 0.2-0.6 weight %. In some implementations, for example, instead of carbon nanotubes, the exemplary metal mesh DSSC structure having the nanostructure configuration 205b in FIG. 2A can be configured to have ˜8 nm diameter TiO₂ nanotubes, as shown in FIG. 3 and FIGS. 4A and 4B.

FIG. 3 shows an exemplary electron micrograph depicting ˜8 nm diameter TiO₂ nanotubes synthesized by an exemplary hydrothermal process, using Ti metal, TiO₂ nanoparticles or Ti butoxide type precursor as the source of Ti during synthesis. To produce the exemplary TiO₂ nanotubes in this example, the reactant chemical during the hydrothermal synthesis was NaOH solution (e.g., but HCl solution can also be used) at ˜120-150° C. For example, the DSSC solar cells were assembled and implemented, e.g., with one-third of ˜20 nm diameter TiO₂ nanoparticles in the anode structure replaced with 8 nm TiO₂ nanotubes, and exhibited 2-4% higher DSSC solar cell efficiency.

FIGS. 4A and 4B show comparative scanning electron microscopy (SEM) micrographs showing the beneficial effect of nanofiber incorporation into the exemplary TiO₂ anode structure layer. The SEM images depict a sheet of −8 nm diameter TiO₂ nanotubes, with FIG. 4A showing an SEM image of the anode structure made of TiO₂ nanoparticles only, and FIG. 4B shows an SEM image of the anode structure made of TiO₂ nanoparticles containing ˜8 nm diameter TiO₂ nanotube fibers. The anode structure made of TiO₂ nanoparticles only was produced by doctor blade coating a paste containing ˜20 nm nanoparticles in a binder and solvent on a flat substrate and by baking for curing (e.g., at 500° C. for 30 minutes). As shown in the SEM image of FIG. 4A, dry mud like cracks visibly occurred; while the anode structure made of TiO₂ nanoparticles but also containing 8 nm diameter TiO2 nanotube fibers exhibited much less micro-cracking, as shown in the SEM image of FIG. 4B. The anode structure made of TiO₂ nanoparticles with 8 nm diameter TiO₂ nanotube fibers was produced by doctor blade coating a paste containing ˜20 nm nanoparticles mixed with 2:1 ratio of 8 nm TiO₂ nanotubes, in a binder and solvent on a flat substrate and by baking for curing. The substantially less micro-cracking may be due to electrical and mechanical connection of TiO₂ nanoparticles by the long TiO₂ nanotubes.

The exemplary anode structure TiO₂ nanoparticle layer in the metal-mesh-electrode containing DSSC device can be configured to contain nanofibers of either single-wall, double-wall, or multi-wall carbon nanotubes. For example, double-wall carbon nanotubes can be configured to be at least 0.1 micrometer long, in which the added amount of nanofibers can be configured to be at least 0.05 wt %, and less than 1 wt %. For example, one preferred composition range includes 0.1-0.5 wt %, e.g., in which the resulting TiO₂ nanoparticle layer structure contain at least 20% less micro-cracks than a similar TiO₂ layer containing no carbon nanotubes.

For the exemplary case of 8 nm TiO₂ nanotube addition to the TiO₂ nanoparticle photoactive layer 205b, an exemplary desired amount of the 8 nm TiO₂ nanotubes to be mixed into the TiO₂ nanoparticle layer can include a range of 2-40 wt %, and in some examples, preferably 5-30 wt %.

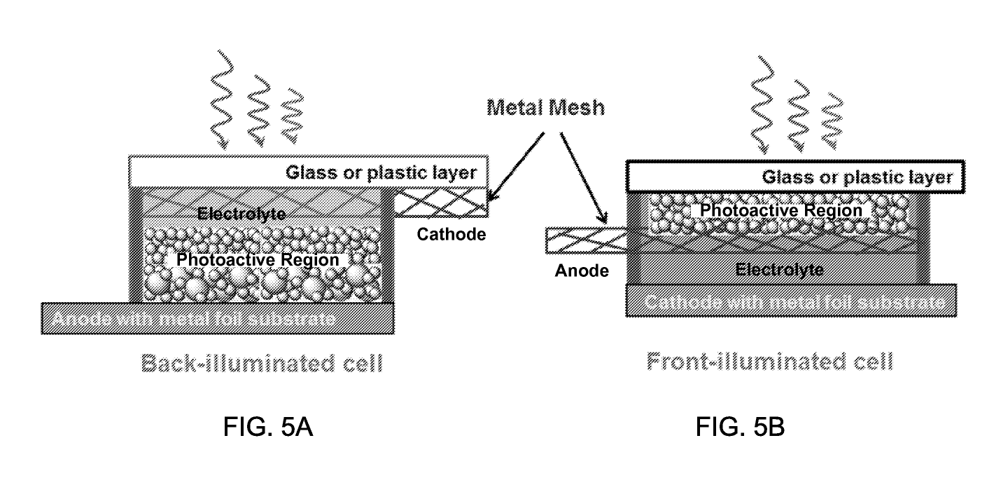

FIGS. 5A and 5B show cross-sectional schematic illustrations of dye-sensitized solar cells including all-metal substrates and a photoactive region including a gradient of exemplary TiO₂ nanoparticle sizes for enhanced solar cell performance. FIG. 5A shows an exemplary back-illuminated DSSC, whereby sunlight passes through cathode and electrolyte before being absorbed by the photoactive anode structure. FIG. 5B shows an exemplary front-illuminated DSSC, whereby the sunlight impinges directly on the photoactive anode structure. For example, the photoactive structure of the DSSC devices shown in FIGS. 5A and 5B can include one or more layers of mixed particle size coupled to the anode of the solar cells. In some implementations, for example, the photoactive structure can include smaller 20 nm type TiO₂ nanoparticles mixed with 200-500 nm regime larger TiO₂ particles for enhancement of solar light reflectance and improved DSSC cell properties in the metal mesh containing DSSC solar cells.

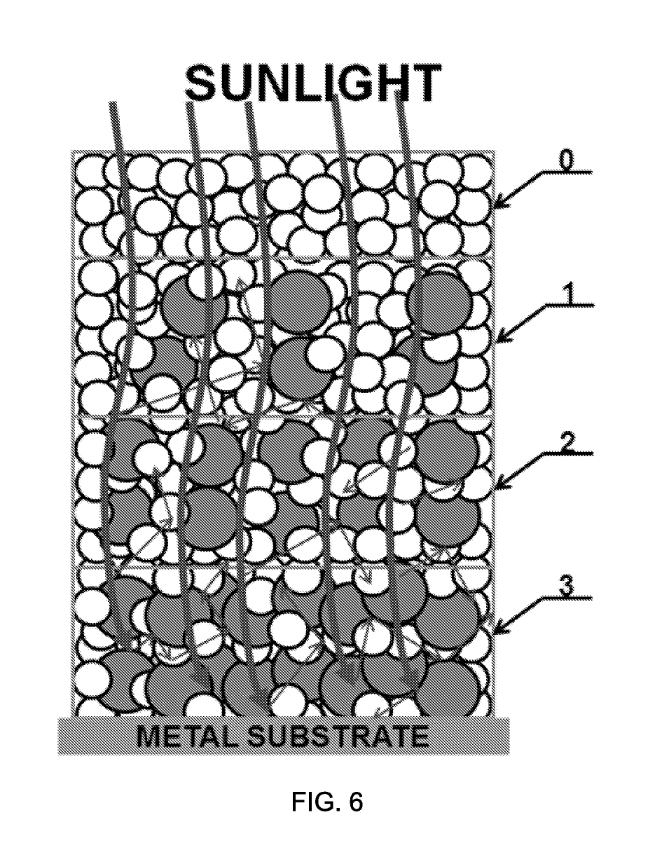

In some implementations, for example, the multi-layer TiO₂ anode layer structure can have at least 2 layers, or at least 4 layers in some other implementations, which is illustrated in FIG. 6. FIG. 6 shows a schematic illustration of an exemplary layered anode structure for a DSSC device of the disclosed technology, e.g., fabricated in combination with a metal substrate. As shown in the schematic, small white circles in the drawing represent ˜20 nm titanium dioxide nanoparticles (TiO₂ NPs), which have high surface-to-volume ratio for optimum dye loading and light harvesting. For example, the small ˜20 nm TiO₂ NPs can provide high surface area for maximizing the amount of dye molecules that are loaded in the mesoporous anode structure, which can be important for efficient light harvesting. The larger darker-colored circles represent ˜500 nm TiO₂ NPs that effectively scatter light.

In the example shown in FIG. 6, the amount of large scattering TiO₂ NPs gradually increases in each layer numbered from “1” to “3”, with the top layer numbered “0” containing no large scattering NPs, thus allowing the maximum adsorption of dye molecules for higher performance. For example, each layer can be configured to be 1-10 μm, or in some examples, preferably 1-5 μm thick. For example, the volume fraction of exemplary 200-800 nm larger light-reflecting particles can be configured in the range of 0-50%, and in some examples, preferably 0-20% with the lowest positioned bottom layer having at most 20% volume of the larger, light reflecting particles.

The absorption path length of the incident light in the nanocrystalline TiO₂ films can be significantly increased by adding light scattering particles, e.g., with dimensions ˜500 nm. These scattering particles can be added to the photo-anodes of the exemplary DSSCs, e.g., including front-illuminated, back-illuminated, and dual-illuminated designs.

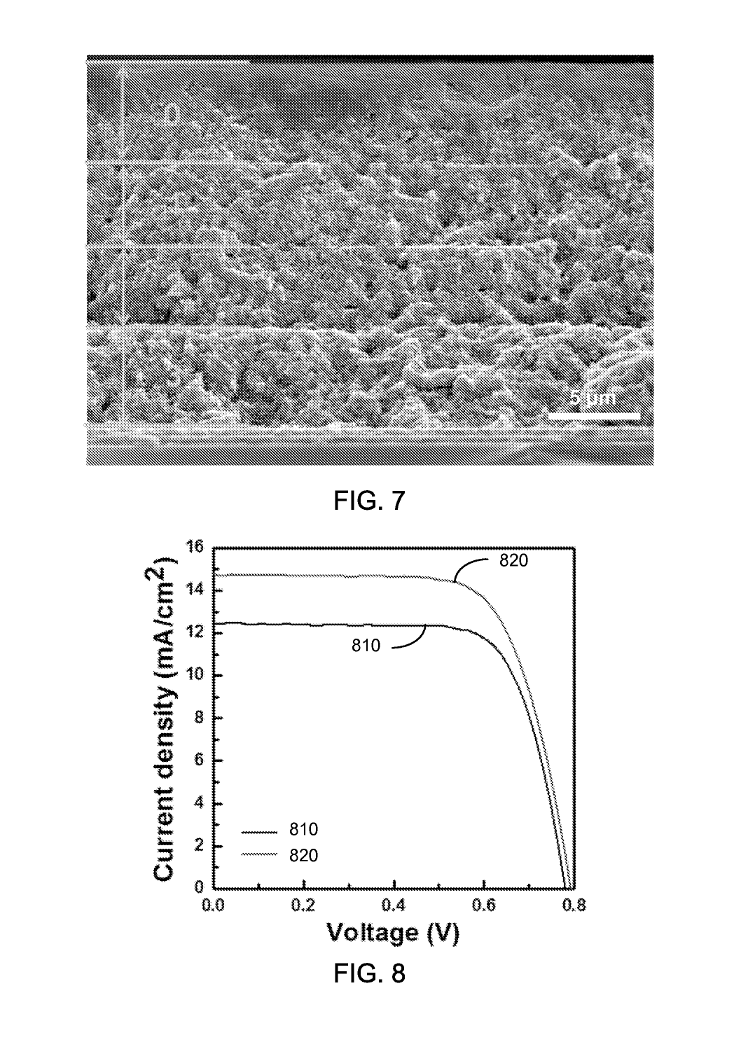

FIG. 7 shows an SEM image of an exemplary layered anode structure, e.g., of the type described in FIG. 5A or 5B, where the amount of large scattering TiO₂ nanoparticles is varied in each layer. The top layer (labeled “0”) is free of the large TiO₂ nanoparticles. The amount of large scattering TiO₂ nanoparticles gradually increases in each layer For example, each of the multilayered anode structures of the disclosed technology can have a layer thickness in the range 1-10 μm, and in some examples, preferably in the range of 2-5 μm. For example, the advantage of having an upper layer without any ‘scatterers’ is shown in the current-voltage curves of FIG. 8.

FIG. 8 shows a data plot of photocurrent voltage (I-V) curves of exemplary back-illuminated DSSCs fabricated with layered structured TiO₂ anode on a metal substrate. The curve 810 and 820 are for solar cells with and without the upper layer (having no large particle ‘scatterers’, e.g., only the structure labeled “0” in FIG. 7).

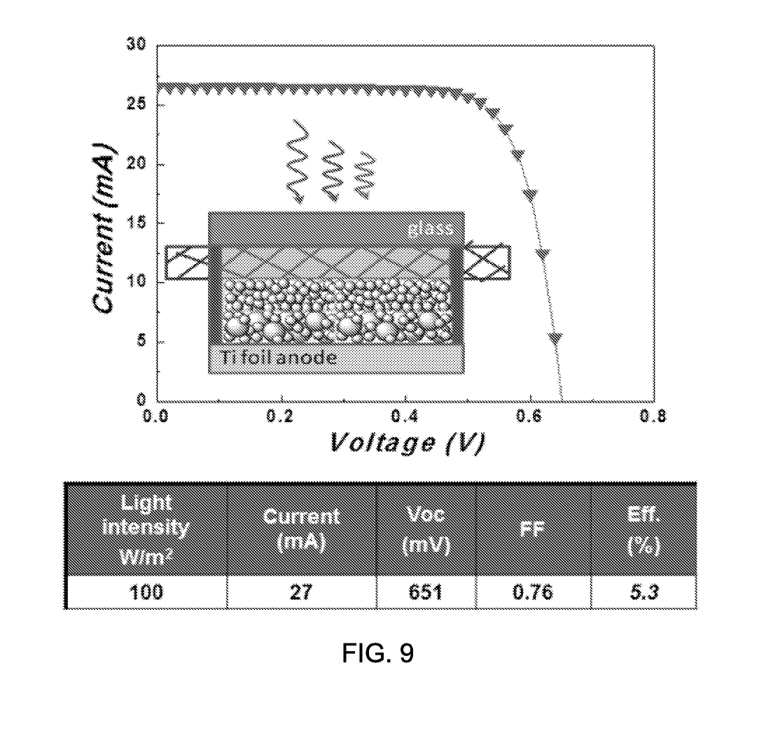

FIG. 9 shows a photocurrent voltage (I-V) plot of an exemplary large-size (e.g., 5×5 cm²), back-illuminated DSSC fabricated with the layered structured TiO₂ anode with light-scattering configuration on a metal substrate, e.g., as depicted in FIGS. 5A, 5B, 6 and 7. As shown in the I-V plot, the layered structure exhibited more than >5% efficiency with all metallic electrode, for the exemplary 5×5 cm² solar cells.

The disclosed DSSC devices can be produced by the following exemplary fabrication processes including anode structure, cathode, and photoactive region preparation techniques, as described below.

Anode Structure Preparation Techniques

Pretreatment methods can include the following exemplary processing steps. For example: (1) Ti foil can be cut to a desired size (e.g., 6×5.3 cm); (2) sonicate in a cleaning solutions using, e.g., 5% detergent aqueous solution, then acetone, then EtOH, for 10 min sonication for each step, followed by N₂ drying; (3) perform HF treatment, e.g., using 1.4 M HF for 2 min, followed by 1 min sonication in DI H₂O, then DI H₂O rinse, followed by N₂ drying; perform Pickle solution treatment, e.g., for 2 min (e.g., where the Pickle solution contains HF/HNO₃/DI H₂O with volume ratio of 1/18/81), followed by 1 min sonication in DI H₂O, then DI H₂O rinse, followed by N₂ drying.

Methods for coating of TiO₂ film can include the following exemplary processing steps. For example: (1) Ti foil can be placed onto vacuum assistance flatter; (2) a screen can be put onto Ti foil; (3) an adhesive tape (e.g., scotch tape) can be applied on the screen along the four edges of Ti foil, e.g., while leaving 1.5 mm space to the edges; (4) M2 paste can be applied onto the screen; (5) first layer of M2 can be coated by rubber blade; (6) the Ti foil can be detached from screen and the paste relaxed until flat and uniform, e.g., which can take 5-10 min; (7) the TiO₂ film can be dried, e.g., on a hot plate at 120° C. for 5 min (8) at least some of these exemplary processing steps can be repeated from the beginning, e.g., for total 3 times. For example, from second coating, the coated TiO₂ film can be relaxed in EtOH vapor for 10 min before dried on hot plate, e.g., which can be effective to maintain the flat and uniform anode for best properties. After multiple (e.g., three) coatings of M2, the paste can be changed to Normal paste, previous tapes can be removed, and the screen can be cleaned well, e.g., by EtOH, in which this same procedure can be repeated for other (e.g., two) coatings. In some exemplary implementations, for example, the final anode structure has three layers of M2 on the bottom and two layers of normal film on the top.

Methods for sintering of TiO₂ film can include the following exemplary processing steps. For example: (1) the coated TiO₂ film can be put into a furnace at room temperature; and (2) the furnace can be heated up to the desired temperature for sintering, e.g., such as 500° C. within 90 min, stay at 500° C. for 30 min, then cooled down automatically.

TiCl₄ treatment methods can include the following exemplary processing steps. For example: (1) the sintered TiO₂ film can be put into 40 mM TiCl₄ aqueous solution, and heated at 70° C. for 30 min; (2) the TiCl₄-treated sample can be rinsed by DI H₂O, followed by N₂ gas drying; and the sample can be sintered again at 500° C. for 30 min.

Dye loading methods can include the following exemplary processing steps. For example, an exemplary dye solution can be applied for a desired time to the sample, e.g., such as 5 mM N719 dye solution for 12 hr.

Cathode Preparation Techniques

Pretreatment methods can include the following exemplary processing steps. For example: (1) Ti mesh or line array structure can be cut to a desired size (e.g., 7×5.3 cm); (2) sonicate in a cleaning solutions using, e.g., 5% detergent aqueous solution, then acetone, then EtOH, for 10 min sonication for each step, followed by N₂ drying; and (3) perform HF treatment, e.g., using 1.4 M HF for 2 min, followed by 1 min sonication in DI H₂O, then DI H₂O rinse, followed by N₂ drying.

Methods for electrodeposition of Pt onto the Ti mesh can include the following exemplary processing steps. For example: (1) the Ti mesh can be immersed into 5 mM H₂PtCl₆.6H₂O/millQ H₂O; (2) Ag/AgCl reference electrode can be assembled on the left, Ti mesh can be assembled in the middle, and Pt foil cathode can be assembled on the right; (3) a cable can be attached to the correct/corresponding electrodes; (4) parameters can be set and applied for standard pulse current deposition, the total applied current density can be set (e.g., 60 mA/cm²), the total applied charge density can be set (e.g., 540 mC/cm₂), the duty cycle can be set (e.g., 5% with 10 ms on time and 190 ms off time); and (5) after such deposition, the Ti mesh can be taken out and dried gently by N₂ gas. The exemplary fabricated cathode is then ready.

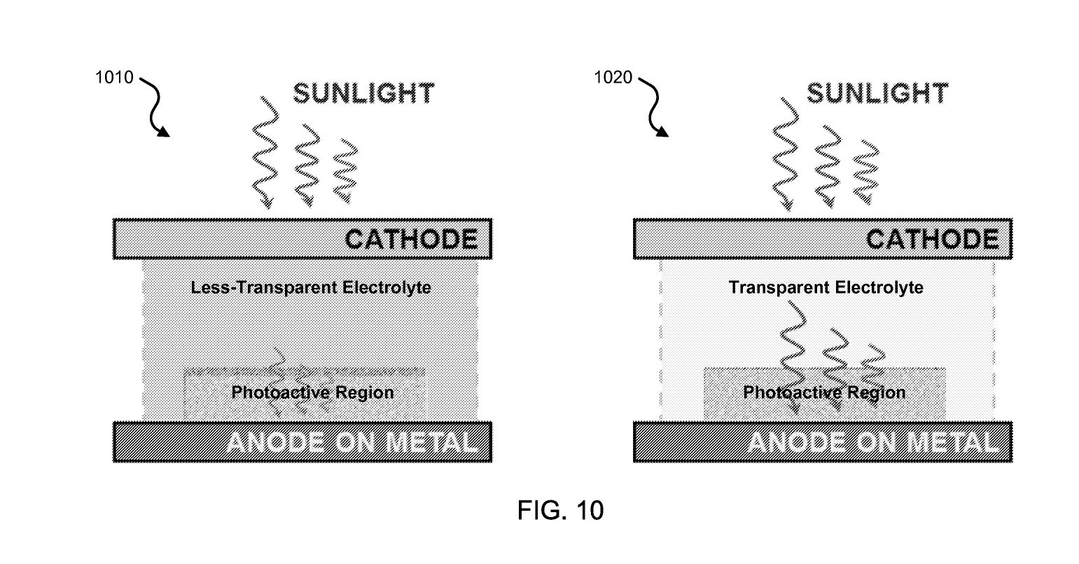

Other exemplary embodiments and implementations of DSSC devices of the disclosed technology are described. FIG. 10 shows a comparative schematic diagram of a DSSC device 1010 having a less transparent electrolyte versus a DSSC device 1020 having a transparent/colorless electrolyte, in which both DSSC devices 1010 and 1020 are configured for back-illumination and include metal electrodes (e.g., metal mesh structure cathode and solid metal structure anode). For example, the DSSC device 1010 can include a conventional iodide/tri-iodide-based electrolyte with sunlight substantially absorbed by the colored tri-iodide component in the electrolyte. For example, the DSSC device 1020 can include has a fully transparent, colorless electrolyte which allows sunlight to pass through without significant light loss. An example opaque electrolyte composition can include a standard BMII based electrolyte of 0.6 M 1-butyl-3-methylimidazolium iodide/0.03 M iodine/0.5 M 4-tert-butylpyridine/0.1 M guanidine thiocyanate in acetonitrile/velaronitrile. An example of the transparent electrolyte can include 0.02 M tetramethylammonium sulfide/0.6 M tetrabutylammonium iodide/0.068 M lithium iodide/0.28 M of 4-tert-butylpyridine/0.05 M guanidine thiocyanate in acetonitrile. For example, implementations of the exemplary DSSC device 1020 can use such transparent electrolytes in configurations of the solar cell devices being FTO-glass-free and including metal mesh electrode. Such exemplary DSSC cells are desirable since the metal mesh tends to cause some decrease in light transmission, and hence the use of transparent electrolyte compensates for some of the reduced light transmission.

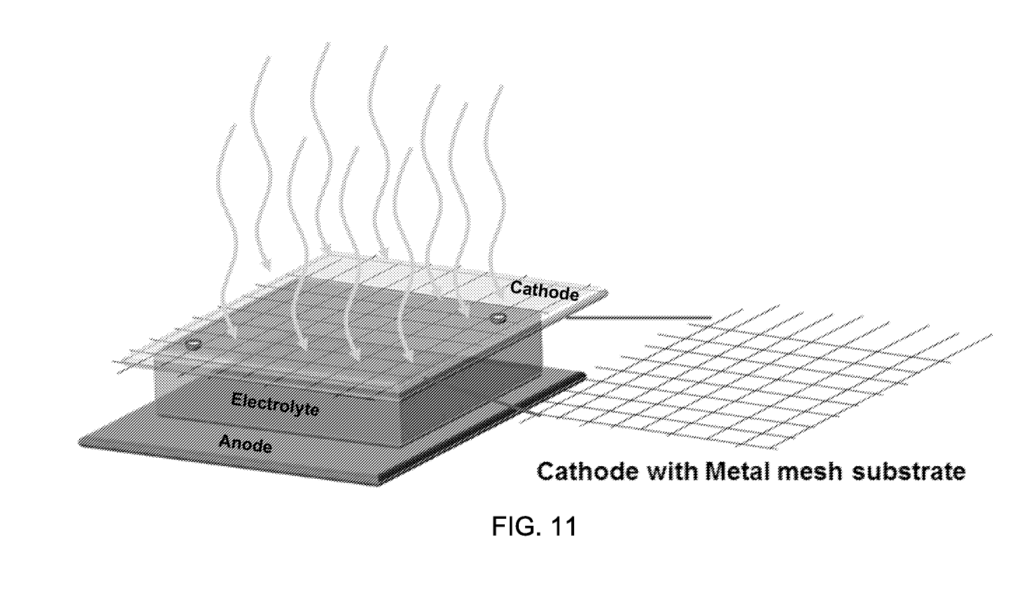

FIG. 11 shows a schematic illustration of an exemplary back-illuminated DSSC showing the top (cathode) side. The exemplary DSSC includes a cathode that includes a metal mesh electrode, which is shown on the right side of the schematic illustration of FIG. 11 without other solar cell components of the exemplary DSSC. The exemplary metal-based cathode of the exemplary DSSC is highly light-transmissive. For example, by selection of the expanded metal foil, or by various mechanical and chemical treatments, the cathode can be made to transmit up to 90% of the incident photons. For example, the desirable range of transmission in the light transmitting metal mesh structure can be configured to be at least 40%, and in some examples, at least 60%, and in some examples, at least 80%.

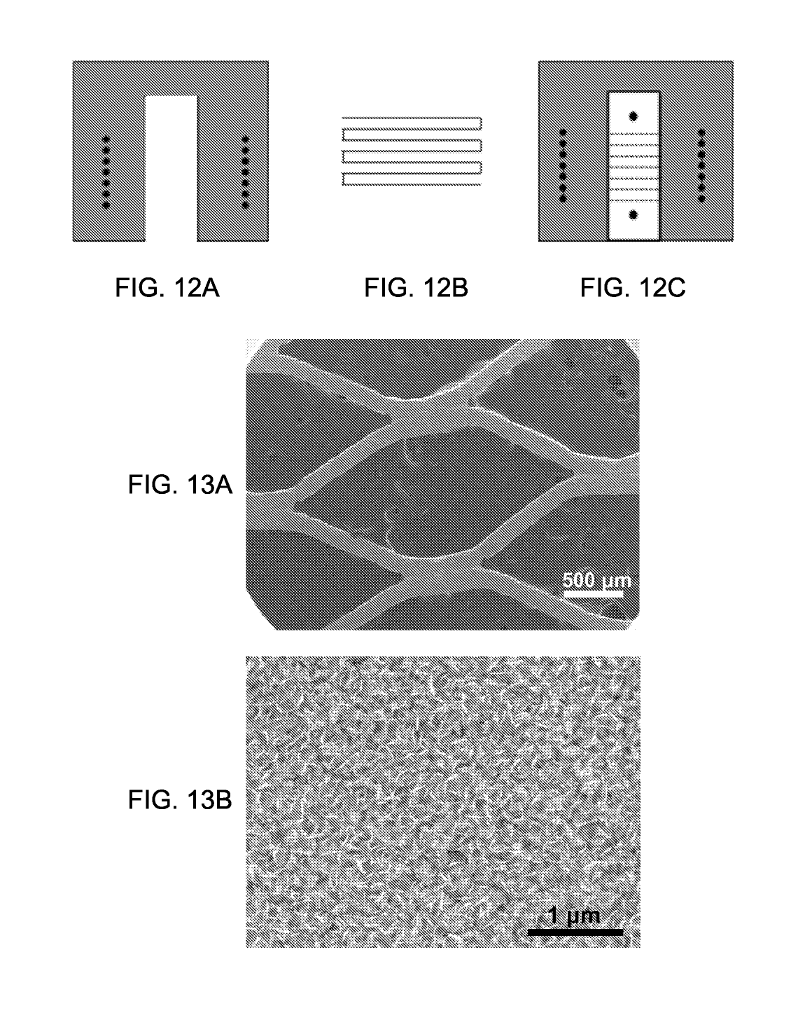

FIGS. 12A-12C show diagrams depicting exemplary designs of a cathode metal wire arrangement. The exemplary metal wire arrangements shown in FIGS. 12A-12C can also be employed for the anode, and can be implemented instead of a metal mesh structure. In some implementations, for example, the wires can be held in place with a metal frame with neighboring holes separated or spaced, e.g., ˜1 mm apart, which is shown in FIG. 12A. Titanium or other wire, e.g., with a diameter in a range of 10-200 μm, can be employed through the holes, such as in a threaded configuration as shown in FIG. 12B. FIG. 12C shows the exemplary cathode including the metal wire arrangement using threaded wire in a frame. In other implementations, for example, as an alternative to the contiguous wire, individual wire segments can be solder-bonded to the metal frame without holes. The wire or wire segments can be, in advance, coated with a catalyst (e.g., platinum nanoparticles) before threading and/or soldering; or alternatively, for example, the catalyst can be deposited on the substrate after attachment to the metal frame.

FIGS. 13A and 13B show SEM images of an exemplary Ti mesh cathode structure. FIG. 13A shows a low magnification SEM of the Ti mesh screen having electrodeposition-coated Pt. FIG. 13B shows a high magnification SEM showing nanoparticles on the Ti mesh surface obtained by using a pulse current deposition technique. For example, the duty cycle of the pulse deposition was 10% with 10 ms of pulse-on time and 90 ms of pulse-off time. The current density utilized was 60 mA/cm², and total charge density was 540 mC/cm². The Pt solution included 5 mM of H₂PtCl₆.6H₂O aqueous solution.

In some implementations, for example, a facile Pt deposition method on Ti metal mesh can be implemented to form a catalyst-coated electrode of the disclosed DSSC devices by electrochemical deposition, e.g., with a desirable coverage of Pt surface by at least 60%, and in some examples at least 80%, and in other examples, preferentially at least 95%. For example, such configurations can result in DSSC current density improved by at least 10%, e.g., as compared with other electrodeposition methods. Various metal mesh types may be used, for example, including, but not limited to, Ti metal mesh, Ti-alloy metal mesh with Ti being present by at least 50 wt %, and not excluding other types of metals, e.g., such as stainless steel, Cu, Ni, Ag, Al, Mo, Zr, Ta, Hf and their alloys containing at least 50 wt % of each of these elements or a combination of these elements (e.g., especially in combination with solid electrolyte or gel electrolyte where these electrolytes have much reduced reactions with the metallic electrodes).

The metal mesh type all-metallic, FTO-glass-free structures demonstrated above for the dye-sensitized solar cells can also applied to perovskite-sensitized solar cells of the disclosed technology. There has been interest in recent years in perovskite-sensitized solar cells, e.g., described in Julian Burschka et al, “Sequential deposition as a route to high-performance perovskite-sensitized solar cells”, Nature 499, 316-320 (July 2013), Mingzhen Liu, et al, “Efficient planar heterojunction perovskite solar cells by vapour deposition”, Nature 501, 395-398 (2013), Jeffrey A. Christians, et al, “An Inorganic Hole Conductor for Organo-Lead Halide Perovskite Solar Cells. Improved Hole Conductivity with Copper Iodide”, J. Am. Chem. Soc. 136, 758-764 (2014). These known perovskite-sensitized solar cells have been mostly assembled using the expensive and high-electrical-resistance FTO (fluorinated tin oxide) type glass. Therefore, it is desirable to eliminate the FTO glass from the perovskite-sensitized solar cells.

In another aspect, the disclosed technology includes high efficiency perovskite-sensitized solar cell devices. The PSSC devices include a cathode coupled to a hole conduction solid electrolyte layer (or layers), an anode coupled to one or more layers of a semiconductive oxide nanostructures, and a perovskite sensitizer layer between the semiconductive oxide nanostructures layer(s) and the hole conduction layer(s), in which the PSSC device generates photoelectric energy based on absorption of light transmitted to the perovskite sensitizer layer through an optically transmissive electrode acting as the cathode, or the anode, or both. Either the cathode or the anode, or both the cathode and the anode, can be configured as a metal mesh structure or metal line array structure permitting transmittance of light through the electrode structure to other portions of the PSSC device. When light is received and transmitted through the PSSC device to the photosensitive photoactive region, the absorption of photons by the perovskite materials results in electron transfer from the perovskite sensitizer layer directly to the conduction band of the nanostructures of the semiconductive oxide and are captured by the anode. Concurrently, the hole conduction solid electrolyte layer provides positive charge (holes) to the cathode, such that there is a flow of electrical energy to a connected circuit between the anode and the cathode.

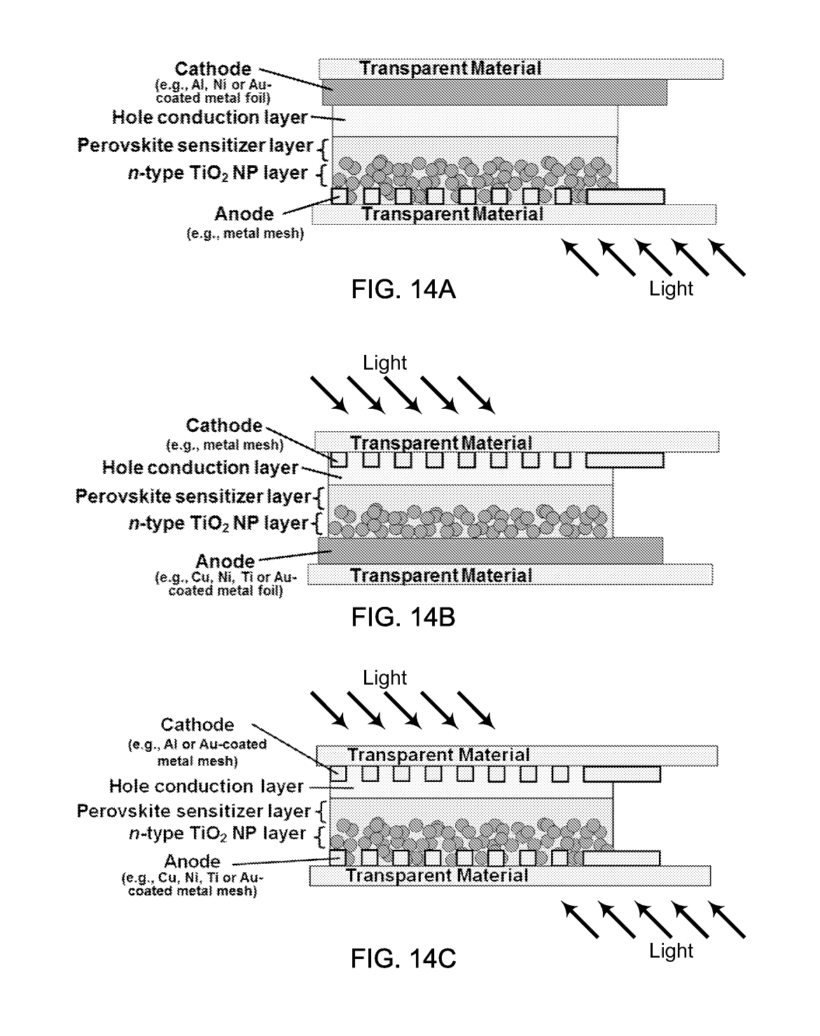

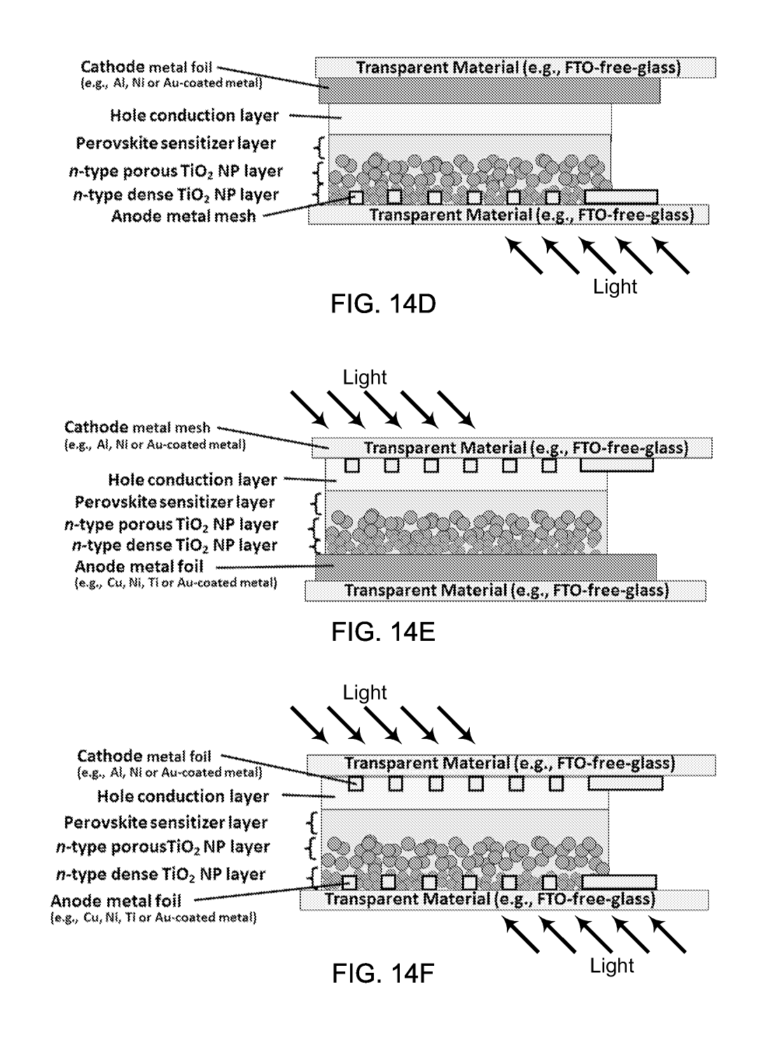

FIGS. 14A-14C show schematic illustrations of exemplary embodiments of FTO-glass-free perovskite-sensitized solar cell devices of the disclosed technology. The exemplary FTO-glass-free PSSC devices of FIGS. 14A-14C include sunlight-transmitting metal mesh electrode structures for the anode, or the cathode, or both the anode or the cathode to provide front-, back-, or dual-illumination PSSC devices.

FIG. 14A shows an exemplary FTO-glass-free PSSC device for front-side illumination through an exemplary sunlight-transmitting metal mesh anode. The exemplary front-illuminated PSSC device includes a metal mesh anode (e.g., such as a mesh screen or wire-line array). The exemplary front-illuminated PSSC device includes a solid metal cathode (e.g., such as a metal foil of, for example, Al, Ni or Au-coated metal). The exemplary front-illuminated PSSC device includes a hole conduction solid electrolyte layer coupled to the cathode, and a perovskite sensitizer layer coupled to the hole conduction solid electrolyte layer. The exemplary front-illuminated PSSC device includes one or more layers of semiconductive oxide nanostructure layers or films (e.g., such as an n-type TiO₂ nanoparticle layer) that is coupled to the anode and the perovskite sensitizer layer. For example, the metal mesh structure anode can be configured in various locations spanning across the one or more layers of semiconductive oxide nanostructure layers, e.g., including at ends of or in between the semiconductive oxide nanostructure layer. In some implementations, for example, the exemplary front-illuminated PSSC device can include a transparent material, e.g., such as regular glass (FTO-free), configured to face incoming light to receive and transmit light to the mesh structure anode; and in some implementations, another FTO-free transparent material can be coupled on the outer side of the cathode.

FIG. 14B shows an exemplary FTO-glass-free PSSC device for back-side illumination through an exemplary sunlight-transmitting metal mesh cathode. The exemplary back-illuminated PSSC device includes a metal mesh cathode (e.g., such as a mesh screen or wire-line array). The exemplary back-illuminated PSSC device includes a solid metal anode (e.g., such as a metal foil of, for example, Cu, Ni, Ti, or Au-coated metal). The exemplary back-illuminated PSSC device includes a hole conduction solid electrolyte layer coupled to the cathode, and a perovskite sensitizer layer coupled to the hole conduction solid electrolyte layer. The exemplary back-illuminated PSSC device includes one or more layers of semiconductive oxide nanostructure layers or films (e.g., such as an n-type TiO₂ nanoparticle layer) that is coupled to the anode and the perovskite sensitizer layer. For example, the metal mesh structure cathode can be configured in various locations spanning across the hole conduction electrolyte layer, e.g., including at ends of or in between the hole conduction electrolyte layer. In some implementations, for example, the exemplary back-illuminated PSSC device can include a transparent material, e.g., such as regular glass (FTO-free), configured to face incoming light to receive and transmit light to the mesh structure cathode; and in some implementations, another FTO-free transparent material can be coupled on the outer side of the anode.

FIG. 14C shows an exemplary FTO-glass-free PSSC device for dual front- and back-side illumination through an exemplary sunlight-transmitting metal mesh anode and cathode. The exemplary dual illuminated PSSC device includes a metal mesh cathode (e.g., such as a mesh screen or wire-line array, which include Al- or Au-coating) and a metal mesh anode (e.g., such as a mesh screen or wire-line array, which can include a Cu, Ni, Ti, or Au-coating). The exemplary dual illuminated PSSC device includes a hole conduction solid electrolyte layer coupled to the cathode, and a perovskite sensitizer layer coupled to the hole conduction solid electrolyte layer. The exemplary dual illuminated PSSC device includes one or more layers of semiconductive oxide nanostructure layers or films (e.g., such as an n-type TiO₂ nanoparticle layer) that is coupled to the anode and the perovskite sensitizer layer. For example, the metal mesh structure cathode and/or anode can be configured in various locations spanning across the hole conduction electrolyte layer and semiconductive oxide nanostructure layer(s), respectively. The exemplary dual illuminated PSSC device can include FTO-free transparent materials, e.g., such as regular glass (FTO-free), configured to face incoming light to receive and transmit light to the mesh structure cathode and mesh structure anode.

FIGS. 14D-14F show schematic illustrations of exemplary embodiments of FTO-glass-free perovskite-sensitized solar cell devices of the disclosed technology. The exemplary FTO-glass-free PSSC devices of FIGS. 14D-14F include sunlight-transmitting metal mesh electrode structures for the anode, or the cathode, or both the anode or the cathode to provide front-, back-, or dual-illumination PSSC devices.

In some implementations, for example, the perovskite sensitizer layer can be configured as a pure thin film, e.g., without any interdigitated oxide. In some implementations, for example, the exemplary FTO-glass-free PSSC devices of FIGS. 14A, 14B, 14C, 14D, 14E, and 14F can include a compact TiO₂ layer between the anode portion and the perovskite sensitizer layer. Yet, in some implementations, the exemplary FTO-glass-free PSSC devices of FIGS. 14A, 14B, 14C, 14D, 14E, and 14F can include a porous TiO₂ that interdigitates with the perovskite sensitizer layer. In other examples, other oxides or insulating scaffolds can be utilized, e.g., including an Al₂O₃ insulator layer coupled to the perovskite sensitizer layer.

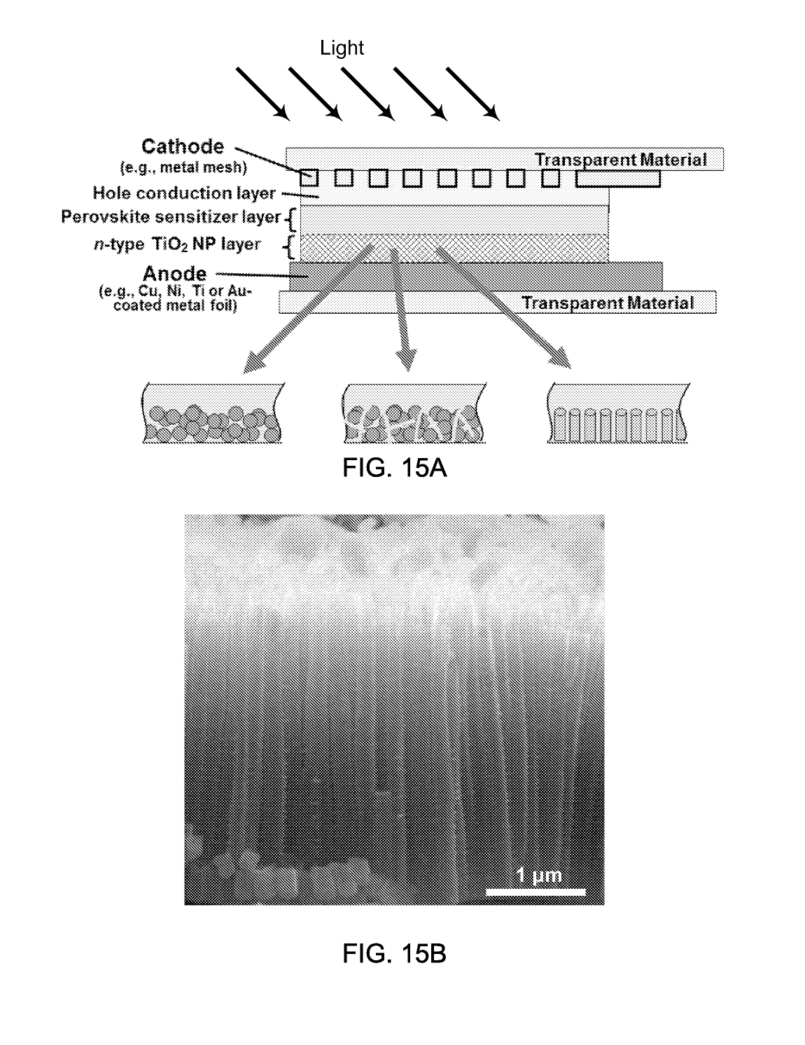

FIG. 15A shows an illustrative schematic of an exemplary back-illuminated FTO-glass-free perovskite-sensitized solar cell device including a transmissive metal mesh cathode and a substantially opaque solid anode, depicting three exemplary configurations of semiconductive oxide nanostructure layer(s) (e.g., n-type TiO₂ nanoparticle layer) coupled to the anode.

The exemplary n-TiO₂ nanoparticle layer(s) of the exemplary back-illuminated FTO-glass-free PSSC device can be configured as one or more nanoparticle-only layer(s). The exemplary n-TiO₂ nanoparticle layer(s) of the exemplary back-illuminated FTO-glass-free PSSC device can be configured as one or more nanoparticle layer(s) with embedded or added internal-void paths, e.g., in which the internal paths are formed by addition of CNTs for enhanced charge transfer or burning removal of carbon fibers/nanotubes to create distributed pores for enhanced perovskite sensitizer penetration. Additionally, for example, the exemplary one or more nanoparticle layer(s) with embedded or added internal-void paths can be employed in exemplary DSSC devices of the disclosed technology, e.g., such as nanostructure 205 of the device 200 in FIG. 2A. The exemplary n-TiO₂ nanoparticle layer(s) of the exemplary back-illuminated FTO-glass-free PSSC device can be configured as a vertical array of nanotubes (e.g., TiO₂ nanotubes). For example, the array of nanotubes can include TiO₂ nanotube array produced by simple anodization of Ti foil substrate for enhanced electrical conduction and perovskite penetration. These exemplary configurations of one or more nanoparticle-only layer(s), one or more nanoparticle layer(s) with embedded or added internal-void paths, and vertical array of nanotubes can be implemented using other semiconductive oxide material nanostructures (e.g., including TiO₂, ZnO, SnO₂, ZrO₂, NiO, Nb₂O₅, WO₃, or Fe₂O₃, or mixtures of them) for both DSSC and PSSC devices of the disclosed technology.

FIG. 15B shows an SEM image showing TiO₂ nanotubes on an exemplary anode Ti foil made by anodization. For example, the intentionally added internal-paths can occupy and desirably contain 1-30 volume % pores, e.g., with the pore volume preferably in the range of 2-15 volume %.

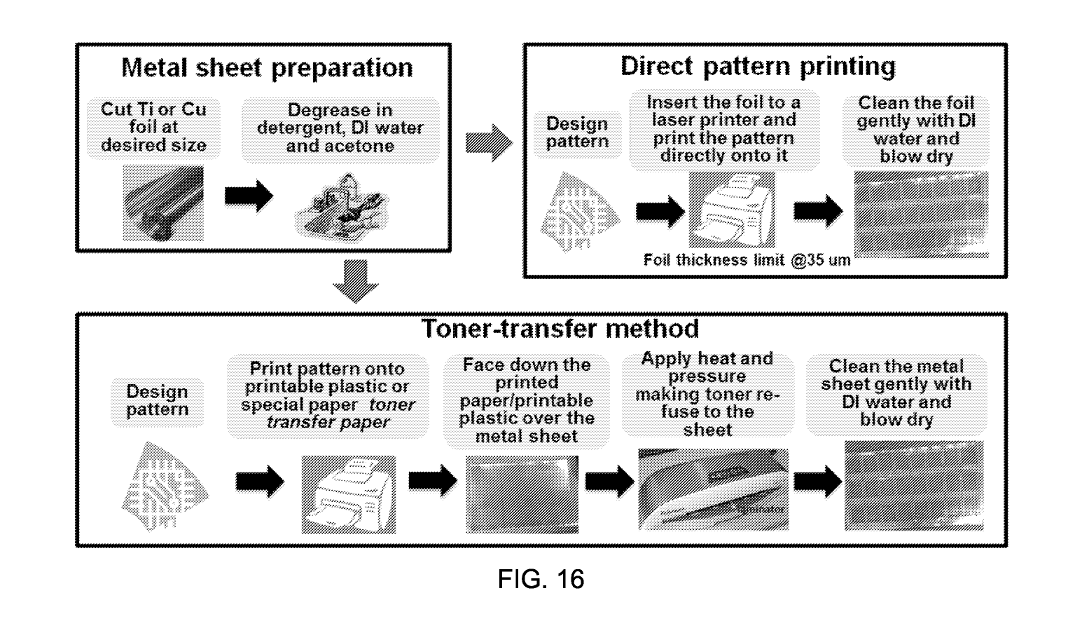

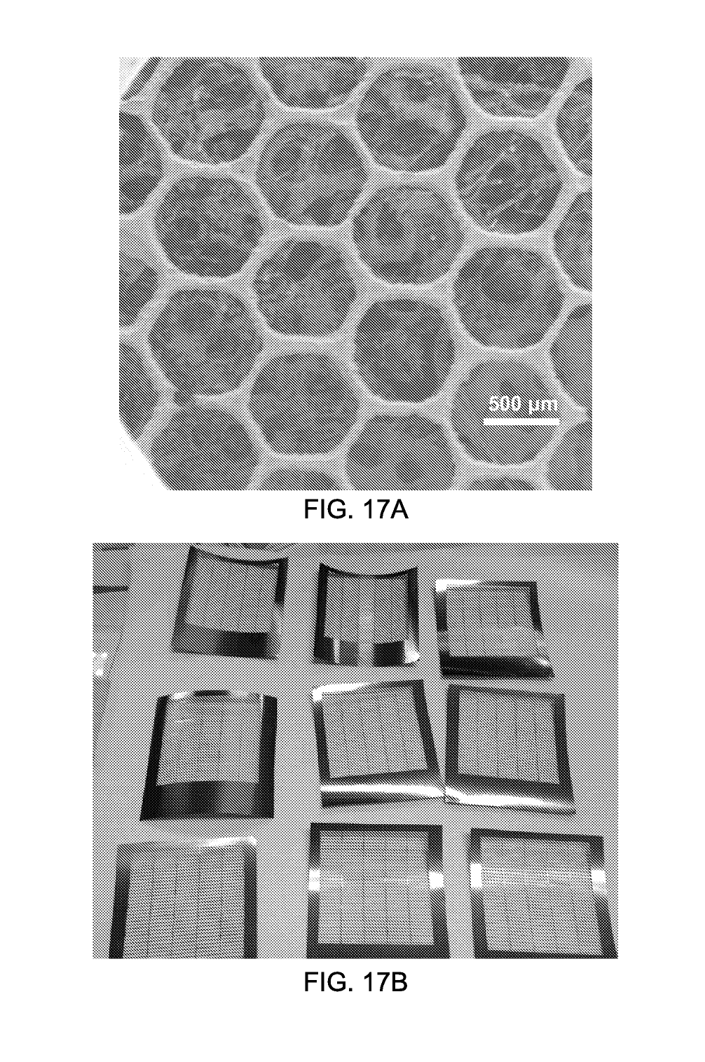

FIG. 16 shows a flow diagram of an exemplary low-cost, high throughput printer-based fabrication method to produce metal mesh electrodes for exemplary electrochemical solar cells of the disclosed technology. For example, the metal mesh electrodes can be produced as conductor screens by chemical etching of pattern-masked metal foils, e.g., such as Ti, Cu, Ni, Al, for use in the DSSC or PSSC solar cells. Some example printed metal patterns are shown in FIGS. 17A and 17B.

For example, a DSSC or a PSSC device of the disclosed technology (e.g., including a cathode, an anode, a semiconductive oxide layer or layers, and an electrolyte formed between the cathode and the anode) can be fabricated by the exemplary low-cost, high throughput method. The method includes process to produce a metal base layer by cutting a metallic foil and cleaning the metallic foil; a process to produce a metal mesh structure by a direct patterning process or a toner transfer process; a process to form one or more layers of a semiconductive oxide formed on the metal base layer, in which the semiconductive oxide include nanostructures having a photosensitive dye material coating; and a process to assemble the electrolyte between the metal mesh structure and the semiconductive oxide layer or layers coupled to the metal base layer, in which an optically transmissive cathode of the solar cell includes the metal mesh structure, an optically opaque anode of the solar cell includes the metal base layer, such that the anode generates photoelectric energy based on absorption of light by the photosensitive dye material. The direct pattering process includes producing a design pattern of a mesh, printing the design pattern on a metal foil to form a pattern-masked metal foil, cleaning the pattern-masked metal foil, and chemically etching the pattern-masked metal foil. The toner transfer process includes producing a design pattern of a mesh, printing the design pattern on a transfer material including a printable plastic or a paper, applying heat and pressure to the transfer material on a metal sheet to form a pattern-masked metal sheet, cleaning the pattern-masked metal sheet, and chemically etching the pattern-masked metal sheet.

FIG. 17A shows an SEM image of an exemplary hexagonal pattern produced by the exemplary inexpensive printing method. FIG. 17B shows images of exemplary slotted metal mesh conductor screens fabricated by the disclosed printer-based pattern masking and chemical etching techniques. For example, Ti, Cu, Ni, stainless steel, Al and their alloys can be patterned, and with a higher resolution 3D printer, pattern features below ˜10 micrometer can be obtained.

For example, such printed pattern metal mesh can be used as is if the dimension is small enough in several micrometers segment line width which can be done with advanced 3D printers. Such micrometer regime metal mesh pattern is desirable in order to cope with short diffusion distance of micrometer in PSSC cells.

These exemplary inexpensively made mesh screens can also be used in combination with nano-network conductors such as nano-patterned graphene, so as to mechanically support fragile nano-pattern conductors.

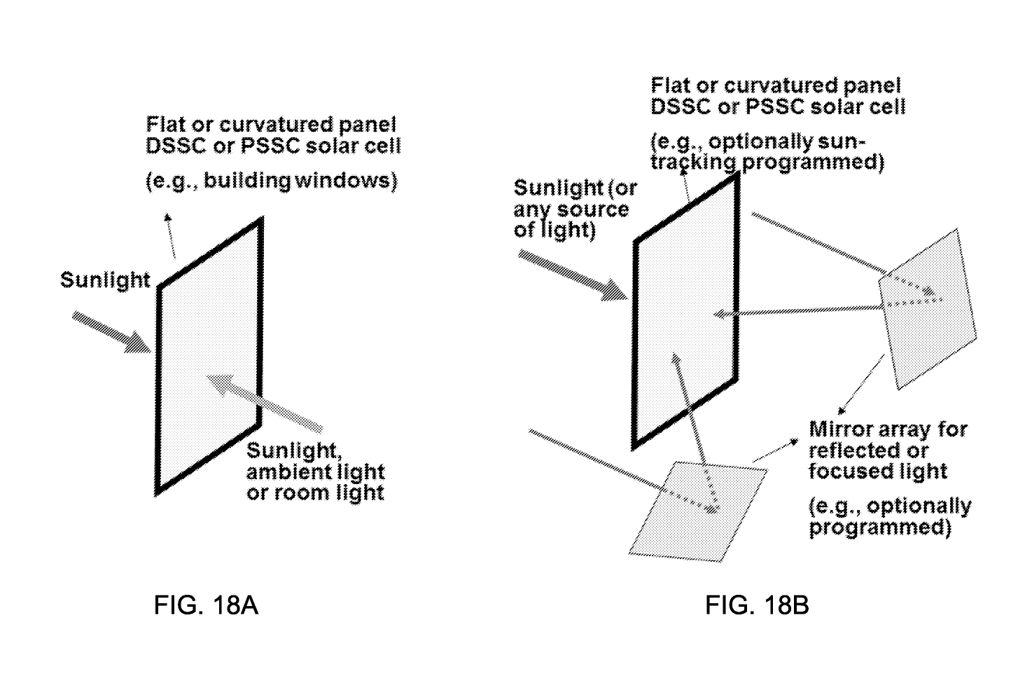

FIGS. 18A and 18B show schematic illustrations of exemplary sunlight harvesting device configurations. As shown in FIG. 18A, an exemplary flat or curvatured panel DSSC or PSSC device of the disclosed technology can be implemented in a structure such as a building to generate electrical energy and transmit light into the building. For example, such DSSC or PSSC devices of FIG. 18A can be used in building windows or outdoor/indoor panel arrays. As shown in FIG. 18B, exemplary DSSC or PSSC devices of the disclosed technology can be activated from reflected or focused sunlight or any light source, using mirror arrays (e.g., optionally sun-tracking-direction programmed), which can, for example, concentrate the light at the DSSC or PSSC device.

In some aspects, the disclosed technology can include a dye-sensitized solar cell apparatus including a cathode with metal substrate, an anode with a metal substrate, at least one layer of a semiconductive oxide and a bound photosensitive dye, and an electrolyte.

In some implementations of the apparatus, the anode can include one or more layers of TiO₂ film attached to the surface of a metallic substrate. In some implementations of the apparatus, the three-dimensional structure can include more than a horizontal plane. In some implementations of the apparatus, the metallic substrate of the anode can include slots, pores, or other openings that allow facile transport of electrolyte ions throughout the anode area. In some implementations of the apparatus, the pores can include nanometer to micrometer-sized pores. In some implementations of the apparatus, the layered TiO₂ film can be configured as back or front illuminated so as to have the cathode positioned on the same or opposite side relative to the incoming solar radiation. In some implementations of the apparatus, the anode can include TiO₂ nanoparticles with one or multiple sizes ranging from nanometer to micrometers. In some implementations of the apparatus, the TiO₂ layer or layers can contain small particles, with the addition of any amount of large particles ranging from 0 wt % to 100 wt %. In some implementations of the apparatus, the anode can include at least one layer of the TiO₂ film, or multilayers. In some implementations of the apparatus, the anode can include TiO₂ films with more amount of large particle contacting to metallic substrate. In some implementations of the apparatus, the anode can include a TiO₂ film with less amount of large particle facing to the side of illumination. In some implementations of the apparatus, the anode can include TiO₂ films with thickness ranging from 0.5 micrometers to 10 micrometers each layer.

In some implementations of the apparatus, the TiO₂ films can be positioned perpendicular to the local surface contour of a three-dimensional metallic structure having at least one of metal wire arrays or woven mesh; metal sheets with perforations, slots, or vertical columns; vertically aligned straight metal sheets; vertically aligned straight metal wires; zigzag vent metal sheets; or slanted or accordion-shaped near-vertical metal sheets. In some implementations of the apparatus, the photon absorption path length can be sufficiently long to allow effective use of the photosensitive dye including an organic dye or a dye mixture.

In some implementations of the apparatus, the dye-sensitized solar cell can be constructed and made free of transparent conductive oxide (TCO) layer on glass.

In some implementations of the apparatus, the electrolyte can be transparent in the visible spectrum. In some implementations of the apparatus, the electrolyte can include a redox shuttle that does not contain iodine. In some implementations of the apparatus, the electrolyte can include at least one of sulfide, polysulfide, organic sulfides, or a mixture of them. In some implementations of the apparatus, the electrolyte can be one of a liquid, a quasi-solid state, or a solid state.

In some implementations of the apparatus, the cathode can include a wire array or mesh of any form. In some implementations of the apparatus, a Ti metal wire, or sheet can be platinized by electrochemical setup, or dip-coating, or spray-coating, or photochemical setup. In some implementations of the apparatus, the Ti wire can be threaded on a metal frame. In some implementations of the apparatus, the Ti wire can be soldered onto both sides of metal frame.

In some aspects, a method includes constructing a dye-sensitized solar cell. Constructing a dye-sensitized solar cell includes coating TiO₂ film layer by layer, drying process in between each layer coating, and annealed anatase structure on a surface of a metallic substrate.

In some implementations of the method, the method can include coating layered TiO₂ film on the surface of metal substrate, and having an anode with layered TiO₂ film with certain thickness, order and number of layers. The method can include using a metal wire or a foil substrate as a conduit for photo-generated electrons from surfaces of the TiO₂anode without a conductive transparent glass. The surfaces of TiO₂ nanoparticle can be dye coated.

In some aspects, a back-illuminated dye-sensitized solar cell device of the disclosed technology includes a cathode including an optically transmissive substrate formed of a metal mesh structure, an anode including a substantially opaque substrate formed of a metal base layer and one or more layers of a semiconductive oxide having a photosensitive dye material coating, the anode generating photoelectric energy based on absorption of light by the photosensitive dye material, and an electrolyte of a substantially transparent substance and formed between the cathode and the anode. The dye-sensitized solar cell is back-illuminated, whereby sunlight first passes through the highly transmissive mesh cathode, then through a thin layer of the transparent electrolyte, and is next absorbed by the photoactive anode. The anode can include a titanium oxide (e.g., including titanium dioxide (TiO₂) film) film and a photosensitive dye coated on the TiO₂ films.

Implementations of the exemplary back-illuminated DSSC device can optionally include one or more of the following exemplary features. For example, instead of a single layer of TiO₂, the anode can include multiple TiO₂ films arranged on a surface of a metallic substrate. The metallic substrate can include any metal or combination of metals, for example titanium (Ti), aluminum (Al), tungsten (W), copper (Cu), iron (Fe), nickel (Ni), stainless steel, brass, bronze, or mixtures of them. The metallic substrate of the anode can be a contiguous foil with no openings, or it can have slots, pores, or other openings that allow facile transport of electrolyte through the anode. The openings can have dimensions ranging from nanometer to micrometer-sizes. The layered TiO₂ anode can be back or front-illuminated so as to have the cathode positioned on the same or opposite side of illumination. For example, the TiO₂ nanoparticles can be synthesized by acidic or basic condition, and in an anatase, rutile or brookite-phase. The TiO₂ particle size can be ranged from 1 nanometer to 10 micrometers. The TiO₂ paste can be prepared by mixing TiO₂ particles with one, or multiple sizes. The weight ratio of small TiO₂ particles and large TiO₂ particles can be varied from 0 wt % to 100 wt %. The TiO₂ film can be prepared by doctor blade squeezing, or screen printing. The anode can include at least one layer of TiO₂ film, or two layers, or multiple layers. The number of layers can be ranged from 1 to 15. In the back-illuminated design, the weight amount of large TiO₂ particles in the TiO₂ film can be gradually increased when approaching the metallic substrate. The TiO₂ film containing relatively small TiO₂ particles can face the side of illumination. The thickness of each layer can range from 0.5 micrometer to 20 micrometer. The TiO₂ anode can be positioned perpendicular to the local surface contour of a three-dimensional metallic structure comprising at least one of: metal wire arrays or woven mesh; metal sheets with perforations, slots, or vertical columns; vertically aligned straight metal sheets; vertically aligned straight metal wires; zig-zag vent metal sheets; and/or slanted or accordion-shaped near-vertical metal sheets.

The electrolyte can be transparent for optimum penetration of sunlight in the back-illuminated configuration of the DSSC. The electrolyte can be made without adding iodine, to avoid the absorption from tri-iodide (I₃⁻). The electrolyte can include a variety of species with low absorption in the visible spectrum, including sulfide, or polysulfide, or organic sulfide components, or mixture of them. The transparent electrolyte can be liquid, gel, or solid state phase.

The cathode substrate can be an open mesh, or a punched foil. The cathode can include a strand or strands of Ti or other wire that is looped on a metal or glass frame. Alternatively the cathode can include wire segments that are solder-bonded to a metal frame. The cathode can have high transmittance that even exceeds 90%. The thickness of metal substrate or wire can range from 10 micrometer to 1000 micrometer. The spacing of each wire can be varied from micrometers to centimeters. The Ti or other metal wire can be coated with a catalyst by electrochemical deposition, dip coating, spray coating, or photochemical reaction. The substrate for supporting the catalyst-coated wire can be any metal or combination of metals, such as titanium (Ti), aluminum (Al), tungsten (W), copper (Cu), or stainless steel.

The exemplary back-illuminated dye-sensitized solar cell can be constructed and made entirely free of transparent conductive oxide (TCO) layer on glass. The cathode can include at least one of metal foil, platinum coated metal, or carbon-coated metal. The photosensitive dye can include a dye or a dye mixture having a peak molar extinction coefficient that exceeds approximately 1000 M⁻¹cm⁻¹ in a region within a solar emission spectrum. The photosensitive dye can include a dye or a dye mixture that absorbs over any portion of useful solar spectrum ranging from 300 nanometers to at least 1,500 nanometers.

In some implementations of the disclosed high-efficiency dye-sensitized solar cells, the DSSCs can have anodes with layered TiO₂ films on metal substrate. The anode of the DSSC can include new type of dye or a mixture of dyes based on enhanced photon absorption path lengths within the anode of the DSSC. The cathode can include Pt coated on a mesh screen, or wire, or foil.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A dye-sensitized solar cell device, comprising:
a cathode including a metal mesh structure that is optically transmissive and electrically conductive;
an anode including a metal base layer that is optically opaque and electrically conductive;
one or more layers of a semiconductive oxide coupled to the anode, the one or more layers of the semiconductive oxide including nanostructures having a photosensitive dye material coating, wherein the anode generates photoelectric energy based on absorption of light by the photosensitive dye material; and
an electrolyte of a substantially transparent substance and formed between the cathode and the one or more layers of a semiconductive oxide.

2. The device as in claim 1, wherein the anode is configured to provide back-illumination of the light transmitted through the optically transmissive cathode and the transparent electrolyte.

3. The device as in claim 1, wherein the semiconductive oxide includes nanoparticles or nanotubes formed of at least one of titanium dioxide (TiO₂), zinc oxide (ZnO), tin dioxide (SnO₂), zirconium dioxide (ZrO₂), nickel oxide (NiO), niobium pentoxide (Nb₂O₅), tungsten trioxide (WO₃), or iron oxide (Fe₂O₃), or a mixture of two or more of them.

4. The device as in claim 3, wherein the one or more layers of semiconductive oxide includes an n-type TiO₂ layer coupled to the metal base layer of the anode.

5. The device as in claim 3, wherein the one or more layers of semiconductive oxide includes at least one of one or more nanoparticle-only layers, one or more layers of nanoparticles with embedded nanofibers or nanotubes, one or more layers of nanoparticle with internal-void paths, or one or more layers of vertical arrays of nanotubes.

6. The device as in claim 5, wherein the embedded nanotubes include carbon nanotubes (CNTs) or TiO₂ nanotubes.

7. The device as in claim 6, wherein the CNTs include double-wall CNTs, or wherein the TiO₂ nanotubes include a diameter of substantially 8 nm.

8. The device as in claim 5, wherein vertical array of nanotubes include TiO₂ nanotube array produced by anodization of a Ti foil substrate.

9. The device as in claim 3, wherein the semiconductive oxide nanostructures include multiple sized TiO₂ nanoparticles including substantially 20 nm TiO₂ nanoparticles and substantially 500 nm TiO₂ nanoparticles.

10. The device as in claim 9, wherein the layers of the semiconductive oxide closer to the metal base layer includes more substantially 500 nm TiO₂ nanoparticles than the layers of the semiconductive oxide further from the metal base layer.

11. The device as in claim 3, wherein the metal base layer includes a metal foil, the metal foil overlaid with the one or more layers of a gradient film of the TiO₂ nanoparticles.

12. The device as in claim 11, wherein the gradient film of the TiO₂ nanoparticles is formed on the metal foil by coating the metal foil with multiple layers of TiO₂ nanoparticle pastes each having a different amount of scattering nanoparticles.

13. The device as in claim 3, wherein the TiO₂ nanoparticles include a size ranging from a nanometer to micrometers.

14. The device as in claim 1, wherein the cathode includes a platinized Ti metal mesh with 90% light transmission.

15. The device as in claim 1, further comprising a transparent material including a glass or a plastic coupled to the cathode, wherein the DSSC device does not include transparent conductive oxide (TCO) or fluorinated tin oxide (FTO) on or within the transparent material.

16. The device as in claim 1, further comprising a transparent material including a glass or a plastic coupled to the anode, wherein the DSSC device does not include TCO or FTO on or within the transparent material.

17. The device as in claim 1, wherein the metal base layer of the anode includes one or more of slots, pores, or other openings that allow facile transport of electrolyte ions throughout the anode area.

18. The device as in claim 17, wherein the pores include a size ranging from a nanometer to micrometers.

19. The device as in claim 1, wherein the one or more layers of the semiconductive oxide include a thickness ranging from 0.5 micrometers to 10 micrometers for each layer.

20. The device as in claim 1, wherein the metal base layer of the anode includes at least one of titanium (Ti), aluminum (Al), tungsten (W), copper (Cu), iron (Fe), nickel (Ni), stainless steel, brass, bronze, or mixtures of them.

21. The device as in claim 1, wherein the substantially transparent substance of the electrolyte does not contain iodine.

22. The device as in claim 1, wherein the substantially transparent substance of the electrolyte includes at least one of sulfide, polysulfide, organic sulfides, or a mixture of them.

23. The device as in claim 1, wherein the electrolyte is configured as a liquid, a quasi-solid state, or a solid state substance.

24. The device as in claim 1, wherein the light is sunlight.

25. The device as in claim 1, further comprising an array of optically reflective surfaces to direct or focus light otherwise not incident upon DSSC device to the cathode of the DSSC device.

26. A dye-sensitized solar cell (DSSC) device, comprising:
a cathode;
an anode;
a photoactive layer coupled to the anode comprising one or more layers of a semiconductive oxide including nanostructures, wherein at least some of the nanostructures are coated by a photosensitive dye material; and
an electrolyte of a substantially transparent substance between the cathode and photoactive layer,
wherein the DSSC device generates photoelectric energy based on absorption of light transmitted to the photoactive layer through an optically transmissive metal electrode structure functioning as the cathode or the anode, or both.

27. The device as in claim 26, wherein the anode includes a solid metal structure and the cathode includes the optically transmissive metal electrode structure, wherein the photoactive layer receives the light that is transmitted through the optically transmissive cathode and the transparent electrolyte.

28. The device as in claim 26, wherein the cathode includes a solid metal structure and the anode includes the optically transmissive metal electrode structure, wherein the photoactive layer receives the light that is transmitted through the optically transmissive anode.

29. The device as in claim 26, wherein the anode and the cathode include the optically transmissive metal electrode structure, wherein the photoactive layer receives the light that is transmitted through the optically transmissive cathode and the transparent electrolyte and transmitted through the optically transmissive anode.

30. The device as in claim 26, wherein the semiconductive oxide includes nanoparticles or nanotubes formed of at least one of titanium dioxide (TiO₂), zinc oxide (ZnO), tin dioxide (SnO₂), zirconium dioxide (ZrO₂), nickel oxide (NiO), niobium pentoxide (Nb₂O₅), tungsten trioxide (WO₃), or iron oxide (Fe₂O₃), or a mixture of two or more of them.

31. The device as in claim 30, wherein the one or more layers of semiconductive oxide includes an n-type TiO₂ layer coupled to the metal base layer of the anode.

32. The device as in claim 30, wherein the one or more layers of semiconductive oxide includes at least one of one or more nanoparticle-only layers, one or more layers of nanoparticles with embedded nanofibers or nanotubes, one or more layers of nanoparticle with internal-void paths, or one or more layers of vertical arrays of nanotubes.

33. The device as in claim 32, wherein the embedded nanotubes include carbon nanotubes (CNTs) or TiO₂ nanotubes.

34. The device as in claim 33, wherein the CNTs include double-wall CNTs, or wherein the TiO₂ nanotubes include a diameter of substantially 8 nm.

35. The device as in claim 32, wherein vertical array of nanotubes include TiO₂ nanotube array produced by anodization of a Ti foil substrate.

36. The device as in claim 30, wherein the TiO₂ nanoparticles include multiple sized TiO₂ nanoparticles including substantially 20 nm TiO₂ nanoparticles and substantially 500 nm TiO₂ nanoparticles.

37. The device as in claim 27, wherein the semiconductive oxide includes multiple sized nanoparticles, wherein the layers of the semiconductive oxide closer to the anode includes more larger sized nanoparticles than the layers of the semiconductive oxide further from the anode.

38. The device as in claim 37, wherein the nanoparticles are TiO₂ nanoparticles having a size ranging from a nanometer to micrometers.

39. The device as in claim 26, wherein the cathode includes at least one of platinum (Pt), gold (Au), silver (Ag), aluminum (Al), or a combination thereof, and wherein the cathode is coated with a platinized coating.

40. The device as in claim 26, wherein the one or more layers of the semiconductive oxide include a thickness ranging from 0.5 micrometers to 10 micrometers for each layer.

41. The device as in claim 26, wherein the substantially transparent substance of the electrolyte does not contain iodine.

42. The device as in claim 26, wherein the substantially transparent substance of the electrolyte includes at least one of sulfide, polysulfide, organic sulfides, or a mixture of them.

43. The device as in claim 26, wherein the electrolyte is configured as a liquid, a quasi-solid state, or a solid state substance.

44. The device as in claim 26, wherein the light is sunlight.

45. The device as in claim 29, further comprising:
a first transparent material coupled to the cathode; and
a second transparent material coupled to the anode,
wherein the transparent material does not include transparent conductive oxide (TCO) or fluorinated tin oxide (FTO) on or within the transparent material.

46. A perovskite-sensitized solar cell (PSSC) device, comprising:
a cathode;
an anode;
a perovskite sensitizer layer configured between the anode and the cathode comprising one or more layers of a perovskite crystals;
a solid electrolyte coupled between the cathode and perovskite sensitizer layer and formed of a substantially transparent substance capable of conducting hole charge carriers; and
one or more layers of a semiconductive oxide nanostructures coupled between the cathode and perovskite sensitizer layer capable of transferring electrons to the anode,
wherein the PSSC device generates photoelectric energy based on absorption of light transmitted to the perovskite sensitizer layer through an optically transmissive metal electrode structure functioning as the cathode or the anode, or both.

47. The device as in claim 46, wherein the anode includes a solid metal structure and the cathode includes the optically transmissive metal electrode structure, wherein the perovskite sensitizer layer receives the light that is transmitted through the optically transmissive cathode and the solid electrolyte.

48. The device as in claim 46, wherein the cathode includes a solid metal structure and the anode includes the optically transmissive metal electrode structure, wherein the perovskite sensitizer layer receives the light that is transmitted through the optically transmissive anode and the one or more layers of a semiconductive oxide nanostructures.

49. The device as in claim 46, wherein the anode and the cathode include the optically transmissive metal electrode structure, wherein the perovskite sensitizer layer receives the light that is transmitted through the optically transmissive cathode and the solid electrolyte and transmitted through the optically transmissive anode and the one or more layers of a semiconductive oxide nanostructures.

50. The device as in claim 46, wherein the semiconductive oxide includes nanoparticles or nanotubes formed of at least one of titanium dioxide (TiO₂), zinc oxide (ZnO), tin dioxide (SnO₂), zirconium dioxide (ZrO₂), nickel oxide (NiO), niobium pentoxide (Nb₂O₅), tungsten trioxide (WO₃), or iron oxide (Fe₂O₃), or a mixture of two or more of them.

51. The device as in claim 50, wherein the one or more layers of semiconductive oxide includes an n-type TiO₂ layer coupled to the metal base layer of the anode.

52. The device as in claim 50, wherein the one or more layers of semiconductive oxide includes at least one of one or more nanoparticle-only layers, one or more layers of nanoparticles with embedded nanofibers or nanotubes, one or more layers of nanoparticle with internal-void paths, or one or more layers of vertical arrays of nanotubes.

53. The device as in claim 52, wherein the embedded nanotubes include carbon nanotubes (CNTs) or TiO₂ nanotubes.

54. The device as in claim 53, wherein the CNTs include double-wall CNTs, or wherein the TiO₂ nanotubes include a diameter of substantially 8 nm.

55. The device as in claim 52, wherein vertical array of nanotubes include TiO₂ nanotube array produced by anodization of a Ti foil substrate.

56. The device as in claim 50, wherein the TiO₂ nanoparticles are structured to include multiple sized TiO₂ nanoparticles including substantially 20 nm TiO₂ nanoparticles and substantially 500 nm TiO₂ nanoparticles.

57. The device as in claim 47, wherein the semiconductive oxide nanostructures includes multiple sized nanoparticles, wherein the layers of the semiconductive oxide nanostructures closer to the anode includes more larger sized nanoparticles than the layers of the semiconductive oxide further from the anode.

58. The device as in claim 46, wherein the semiconductive oxide nanostructures are TiO₂ nanoparticles having a size ranging from a nanometer to micrometers.

59. The device as in claim 46, wherein the cathode includes at least one of platinum (Pt), gold (Au), silver (Ag), aluminum (Al), or a combination thereof, and wherein the cathode is coated with a platinized coating.

60. The device as in claim 46, wherein the one or more layers of the semiconductive oxide nanostructures include a thickness ranging from 0.5 micrometers to 10 micrometers for each layer.

61. A solar cell device comprising a cathode, an anode, a semiconductive oxide layer or layers coupled to the anode, and an electrolyte of a optically transmissive substance formed between the cathode and the semiconductive oxide layer or layers, the solar cell device fabricated by a method, comprising:
producing a metal base layer by cutting a metallic foil and cleaning the metallic foil;
producing a metal mesh structure by a direct patterning process or a toner transfer process;
forming one or more layers of a semiconductive oxide formed on the metal base layer, the semiconductive oxide including nanostructures having a photosensitive dye material coating; and
assembling the electrolyte between the metal mesh structure and the semiconductive oxide layer or layers coupled to the metal base layer,
wherein the direct pattering process includes:
producing a design pattern of a mesh,
printing the design pattern on a metal foil to form a pattern-masked metal foil,
cleaning the pattern-masked metal foil, and
chemically etching the pattern-masked metal foil,
and wherein the toner transfer process includes:
producing a design pattern of a mesh,
printing the design pattern on a transfer material including a printable plastic or a paper,
applying heat and pressure to the transfer material on a metal sheet to form a pattern-masked metal sheet,
cleaning the pattern-masked metal sheet, and
chemically etching the pattern-masked metal sheet,
wherein an optically transmissive cathode of the solar cell includes the metal mesh structure, an optically opaque anode of the solar cell includes the metal base layer having the one or more layers of a semiconductive oxide formed on the metal base layer, such that the anode generates photoelectric energy based on absorption of light by the photosensitive dye material.
